(19) United States
(12) Patent Application Publication
(10) Pub. No.: US 2025/0178234 A1
(43) Pub. Date: Jun. 5, 2025

(54) METHOD OF ADDITIVELY MANUFACTURING HIGH-PURITY SILICON, METHOD OF ADDITIVELY MANUFACTURING SEMICONDUCTOR MANUFACTURING EQUIPMENT COMPONENT, SEMICONDUCTOR MANUFACTURING EQUIPMENT COMPONENT, AND METHOD OF FORMING SEMICONDUCTOR MANUFACTURING EQUIPMENT COMPONENT

(71) Applicant: Tokyo Electron Limited, Tokyo (JP)

(72) Inventors: Takayuki ISHII, Miyagi (JP); Michishige SAITO, Miyagi (JP); Kazuya NAGASEKI, Miyagi (JP); Akihiko CHIBA, Miyagi (JP); Kenta AOYAGI, Miyagi (JP); Hao WANG, Miyagi (JP)

(73) Assignee: Tokyo Electron Limited, Tokyo (JP)

(21) Appl. No.: 19/042,997

(22) Filed: Jan. 31, 2025

Related U.S. Application Data
(63) Continuation of application No. PCT/JP2023/026319, filed on Jul. 18, 2023.

(30) Foreign Application Priority Data
Aug. 1, 2022 (JP) 2022-122498
Nov. 11, 2022 (JP) 2022-180766

(51) Int. Cl. B28B 1/00; B33Y 10/00; B33Y 30/00; B33Y 40/10; B33Y 80/00; H01J 37/32; H01L 21/683

(52) U.S. Cl. CPC B28B 1/001; B33Y 10/00; B33Y 30/00; B33Y 40/10; B33Y 80/00; H01L 21/6833; H01J 37/32715; H01J 2237/2007

(57) ABSTRACT

A method of additively manufacturing a high-purity silicon includes: turning an interior of a vacuum processing container into a high vacuum state; heating a base plate disposed in the interior of the vacuum processing container; depositing silicon powder on the base plate; forming a molten silicon layer by scanning an energy beam on the base plate; and forming a solidified silicon layer by cooling the molten silicon layer, wherein a cycle including the depositing the silicon powder, the forming the molten silicon layer, and the forming the solidified silicon layer is repeatedly executed.

### CROSS-REFERENCE TO RELATED APPLICATIONS

This application is a bypass continuation application of international application No. PCT/JP2023/026319 having an international filing date of Jul. 18, 2023 and designating the United States, the international application being based upon and claiming the benefit of priority from Japanese Patent Application Nos. 2022-180766 and 2022-122498, filed on Nov. 11, 2022 and Aug. 1, 2022, respectively, the entire contents of each are incorporated herein by reference.

### TECHNICAL FIELD

The present disclosure relates to a method of additively manufacturing a high-purity silicon, a method of additively manufacturing a semiconductor manufacturing equipment component, the semiconductor manufacturing equipment component, and a method of forming the semiconductor manufacturing equipment component.

### BACKGROUND

Patent Document 1 discloses a component forming method that includes an operation of supplying a raw material of a first ceramic and a raw material of a second ceramic different from the first ceramic and irradiating an energy beam onto the raw materials. Patent Document 2 discloses a component forming method that includes an operation of supplying a raw material of a component according to a surface condition of the component and irradiating an energy beam onto the raw material.

### PRIOR ART DOCUMENT

### Patent Documents

Patent Document 1: Japanese Laid-Open Patent Publication No. 2019-201087
Patent Document 2: Japanese Laid-Open Patent Publication No. 2019-201088

### SUMMARY

According to one embodiment of the present disclosure, a method of additively manufacturing a high-purity silicon includes: turning an interior of a vacuum processing container into a high vacuum state; heating a base plate disposed in the interior of the vacuum processing container; depositing silicon powder on the base plate; forming a molten silicon layer by scanning an energy beam on the base plate; and forming a solidified silicon layer by cooling the molten silicon layer, wherein a cycle including the depositing the silicon powder, the forming the molten silicon layer, and the forming the solidified silicon layer is repeatedly executed.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a cross-sectional view showing a configuration example of a plasma processing system.

FIG. 2 is a cross-sectional view showing a configuration example of an additive manufacturing apparatus.

FIG. 3 is an explanatory diagram showing an example of a method of producing a solidification material.

FIG. 4 is an explanatory diagram showing a configuration example of a composite material powder as the solidification material.

FIG. 5 is an explanatory diagram showing a configuration example of a mixed material powder as the solidification material.

FIG. 6 is a flowchart showing main operations of an additive manufacturing process according to an embodiment.

FIG. 7 is an explanatory diagram showing an example of a change in temperature of the solidification material when being irradiated with an electron beam.

FIG. 8 is an explanatory diagram showing a change in energy density of the solidification material shown in FIG. 7.

FIG. 9 is an explanatory diagram showing an example of a change in temperature of the solidification material when being irradiated with the electron beam.

FIG. 10 is an explanatory diagram showing a change in energy density of the solidification material shown in FIG. 9.

FIG. 11 is a flowchart showing main operations of a repairing process for a semiconductor manufacturing equipment component according to an embodiment.

FIG. 12 is a table showing a relationship between various parameters relating to an additive manufacturing process and a density of a manufactured object.

FIG. 13 is an explanatory diagram showing an outline of the manufactured object.

FIG. 14 is a graph plotted by varying a current and scan speed of the electron beam.

FIG. 15A is an explanatory diagram showing a polycrystalline structure in a cross section of the semiconductor manufacturing equipment component.

FIG. 15B is an explanatory diagram showing a polycrystalline structure in the cross section of the semiconductor manufacturing equipment component.

FIG. 16A is an explanatory diagram showing a monocrystalline structure in the cross section of the semiconductor manufacturing equipment component.

FIG. 16B is an explanatory diagram showing a monocrystalline structure in the cross section of the semiconductor manufacturing equipment component.

FIG. 17 is a cross-sectional view showing a configuration example of a plasma processing system according to another embodiment.

FIG. 18 is an explanatory diagram showing a configuration example of a manufactured body formed by gradation manufacturing.

FIG. 19 is an explanatory diagram showing a configuration example of the manufactured body formed by the gradation manufacturing.

FIG. 20 is an explanatory diagram showing a configuration example of the manufactured body formed by the gradation manufacturing.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a semiconductor device manufacturing process, a processing gas supplied into a chamber is excited to generate plasma so as to perform various plasma processes such as an etching process, a film formation process, a diffusion process, and the like on a semiconductor substrate (hereinafter simply referred to as “substrate”) arranged in an internal space of the chamber.

An in-chamber member made of a high-purity silicon-containing material is disposed inside an interior of a plasma processing apparatus for performing the plasma processes. However, it is difficult to manufacture the silicon-containing material into a complex shape without causing cracks or defects. As a result, there are limitations on the shape and dimensions of the in-chamber member to be manufactured.

An additive manufacturing method (so-called 3D printing technology) is used to manufacture a hard-to-manufacture object having a complex shape. In the additive manufacturing method, an additive manufacturing using conductive metallic materials has been implemented. Further, there is a need to implement an additive manufacturing using a high-purity silicon-containing material constituting the above-mentioned in-chamber member. In this case, the high-purity is a purity of 99% or more, for example, a purity of 99.99%, a purity of 99.999%, and a purity of 99.9999%. When an even higher purity is required, for example, the high-purity is a purity of 99.999999999%.

The technology according to the present disclosure, which has been made in consideration of the above circumstances, uses the additive manufacturing method to appropriately manufacture a semiconductor manufacturing equipment component made of a high-purity silicon-containing material. Hereinafter, the additive manufacturing method according to an embodiment and a plasma processing system to which the semiconductor manufacturing equipment component molded by the additive manufacturing method is applied will be described with reference to the drawings. In this specification and the drawings, elements having substantially the same functional configuration will be designated by the same reference numerals, and duplicated descriptions thereof will be omitted.

### <Plasma Process System>

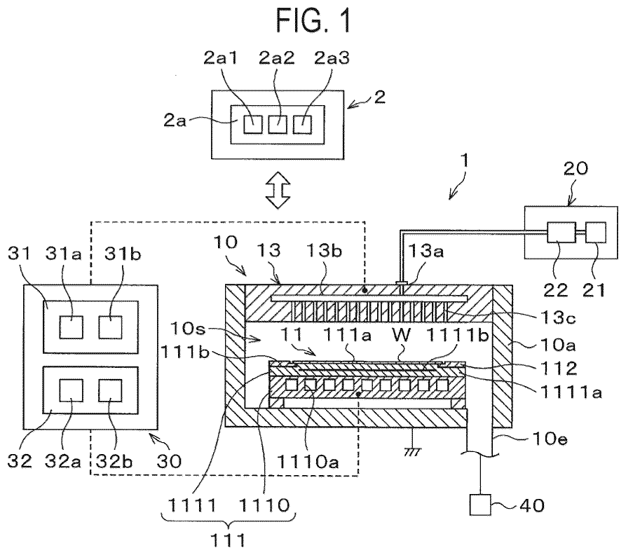

FIG. 1 is a diagram for explaining an example of a configuration of the plasma processing system. In one embodiment, the plasma processing system includes a plasma processing apparatus 1 and a controller 2. As an example, the plasma processing system includes a capacitively-coupled plasma processing apparatus 1.

The capacitively-coupled plasma processing apparatus 1 includes a plasma processing chamber 10, a gas supplier 20, a power supply 30, and an exhaust system 40. The plasma processing apparatus 1 also includes a substrate support 11 and a gas introducer. The substrate support 11 is arranged inside the plasma processing chamber 10. The gas introducer is configured to introduce at least one processing gas into the plasma processing chamber 10. The gas introducer includes a shower head 13. The shower head 13 is disposed above the substrate support 11. In one embodiment, the shower head 13 constitutes at least a portion of a ceiling of the plasma processing chamber 10. Inside the plasma processing chamber 10, there is formed a plasma processing space 10s which is defined by the shower head 13, a sidewall 10a of the plasma processing chamber 10, and the substrate support 11. The plasma processing chamber 10 includes at least one gas supply port for supplying at least one processing gas to the plasma processing space 10s therethrough, and at least one gas exhaust port for exhausting the gas from the plasma processing space 10s therethrough. The plasma processing chamber 10 is grounded. The shower head 13 and the substrate support 11 are electrically isolated from the plasma processing chamber 10.

The substrate support 11 includes a main body 111 and a ring assembly 112. An upper surface of the main body 111 has a central region 111a for supporting a substrate W and an annular region 111b for supporting the ring assembly 112. A wafer is an example of the substrate W. The annular region 111b surrounds the central region 111a in a plan view. The substrate W is arranged on the central region 111a, and the ring assembly 112 is disposed on the annular region 111b so as to surround the substrate W on the central region 111a. Therefore, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. In one embodiment, the base 1110 is made of a silicon-containing material such as silicon (Si) or silicon carbide (SiC). The base 1110 may function as a lower electrode. The electrostatic chuck 1111 is arranged on the base 1110. The electrostatic chuck 1111 includes a ceramic member 1111a and an electrostatic electrode 1111b disposed inside the ceramic member 1111a. The ceramic member 1111a has the central region 111a. In one embodiment, the ceramic member 1111a also has the annular region 111b. Other members surrounding the electrostatic chuck 1111, such as the annular electrostatic chuck or the annular insulating member, may have the annular region 111b. In this case, the ring assembly 112 may be arranged on the annular electrostatic chuck or the annular insulating member, or may be disposed on both the electrostatic chuck 1111 and the annular insulating member. In addition, at least one RF/DC electrode connected to an RF (Radio Frequency) power supply 31 and/or a DC (Direct Current) power supply 32 described later functions as a lower electrode. When a bias RF signal and/or a DC signal described later is supplied to at least one RF/DC electrode, the RF/DC electrode is also referred to as a bias electrode. A conductive member of the base 1110 and at least one RF or DC electrode may function as a plurality of lower electrodes. Further, the electrostatic electrode 1111b may function as the lower electrode. Therefore, the substrate support 11 includes at least one lower electrode. The base 1110 (lower electrode) may be a semiconductor manufacturing equipment component molded by the additive manufacturing method according to the embodiment.

The ring assembly 112 includes one or more annular members. In one embodiment, the one or more annular members include one or more edge rings and at least one cover ring. The edge rings are made of a conductive material or an insulating material, and the cover ring is made of an insulating material. The ring assembly 112 may be the semiconductor manufacturing equipment component molded by the additive manufacturing method according to the embodiment.

The substrate support 11 may also include a temperature adjustment module configured to adjust a temperature of at least one of the electrostatic chuck 1111, the ring assembly 112, or the substrate W to a target temperature. The temperature adjustment module may include a heater, a heat transfer medium, a flow path 1110a, or a combination thereof. A heat transfer fluid such as a brine or a gas flows through the flow path 1110a. In one embodiment, the flow path 1110a is formed inside the base 1110, and one or more heaters are arranged inside the ceramic member 1111a of the electrostatic chuck 1111. The substrate support 11 may also include a heat-transfer-gas supplier configured to supply a heat transfer gas to a gap between a back surface of the substrate W and the central region 111a.

The shower head 13 is configured to introduce at least one processing gas from the gas supplier 20 into the plasma processing space 10s. The shower head 13 includes at least one gas supply port 13a, at least one gas diffusion chamber 13b, and a plurality of gas introduction holes 13c. The processing gas supplied to the gas supply port 13a passes through the gas diffusion chamber 13b and is introduced into the plasma processing space 10s from the plurality of gas introduction holes 13c. The shower head 13 also includes at least one upper electrode. The gas introducer may include, in addition to the shower head 13, one or more side gas injectors (SGI: Side gas injector) attached to one or more openings formed on the sidewall 10a. In one embodiment, the shower head 13 (upper electrode) is made of a silicon-containing material such as silicon (Si) or silicon carbide (SiC). That is, the upper electrode may be the semiconductor manufacturing equipment component molded by the additive manufacturing method according to the embodiment.

The gas supplier 20 may include at least one gas source 21 and at least one flow rate controller 22. In one embodiment, the gas supplier 20 is configured to supply at least one processing gas from the gas source 21 to the shower head 13 via the flow rate controller 22. The flow rate controller 22 may include, for example, a mass flow controller or a pressure-controlled flow rate controller. Further, the gas supplier 20 may include one or more flow modulation devices configured to modulate or pulse a flow rate of the at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. This causes plasma to be formed from at least one processing gas supplied to the plasma processing space 10s. Thus, the RF power supply 31 may function as at least a portion of a plasma generator configured to generate plasma from one or more processing gases in the plasma processing chamber 10. In addition, a bias potential is generated on the substrate W by supplying a bias RF signal to the at least one lower electrode, and ion components in the plasma thus formed may be attracted to the substrate W.

In one embodiment, the RF power supply 31 includes a first RF generator 31a and a second RF generator 31b. The first RF generator 31a is coupled to at least one lower electrode and/or at least one upper electrode via at least one impedance matching circuit and configured to generate a source RF signal (source RF power) for plasma generation. In one embodiment, the source RF signal has a frequency in a range of 10 MHz to 150 MHz. In one embodiment, the first RF generator 31a may be configured to generate a plurality of source RF signals having different frequencies. The one or more source RF signals thus generated are supplied to at least one lower electrode and/or at least one upper electrode.

The second RF generator 31b is coupled to at least one lower electrode via at least one impedance matching circuit and configured to generate a bias RF signal (bias RF power). A frequency of the bias RF signal may be the same as or different from that of the source RF signal. In one embodiment, the bias RF signal has a lower frequency than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The one or more bias RF signals thus generated are provided to at least one lower electrode. Further, in various embodiments, at least one of the source RF signal or the bias RF signal may be pulsed.

Further, the power supply 30 may include a DC power supply 32 coupled to the plasma processing chamber 10. The DC power supply 32 includes a first DC generator 32a and a second DC generator 32b. In one embodiment, the first DC generator 32a is connected to at least one lower electrode and configured to generate a first DC signal. The first bias DC signal thus generated is applied to the at least one lower electrode. In one embodiment, the second DC generator 32b is connected to at least one upper electrode and configured to generate a second DC signal. The second DC signal thus generated is applied to the at least one upper electrode.

In various embodiments, at least one of the first DC signal or the second DC signal may be pulsed. In this case, a sequence of voltage pulses is applied to at least one lower electrode and/or at least one upper electrode. The voltage pulses may have a rectangular pulse waveform, a trapezoidal pulse waveform, a triangular pulse waveform, or a combination thereof. In one embodiment, a waveform generator for generating the sequence of voltage pulses from the DC signal is connected between the first DC generator 32a and at least one lower electrode. Thus, the first DC generator 32a and the waveform generator constitute a voltage pulse generator. When the second DC generator 32b and the waveform generator constitute a voltage pulse generator, the voltage pulse generator is connected to at least one upper electrode. The voltage pulses may have a positive polarity or a negative polarity. Further, the sequence of voltage pulses may include one or more positive polarity voltage pulses and one or more negative polarity voltage pulses in one period. The first and second DC generators 32a and 32b may be provided in addition to the RF power supply 31, or the first DC generator 32a may be provided in place of the second RF generator 31b.

The exhaust system 40 may be connected to, for example, a gas exhaust port 10e provided at the bottom of the plasma processing chamber 10. The exhaust system 40 may include a pressure regulation valve and a vacuum pump. The pressure regulation valve regulates an internal pressure of the plasma processing space 10s. The vacuum pump may include a turbo-molecular pump, a dry pump, or a combination thereof.

The controller 2 processes computer-executable instructions that cause the plasma processing apparatus 1 to execute various operations described in the present disclosure. The controller 2 may be configured to control individual elements of the plasma processing apparatus 1 to execute various operations described herein. In one embodiment, a portion or the entirety of the controller 2 may be included in the plasma processing apparatus 1. The controller 2 may include a processor 2a1, a memory 2a2, and a communication interface 2a3. The controller 2 is implemented by, for example, a computer 2a. The processor 2al may be configured to perform various control operations by reading a program from the memory 2a2 and executing the read program. This program may be stored in the memory 2a2 in advance, or may be acquired via a medium when necessary. The acquired program is stored in the memory 2a2 and is read from the memory 2a2 and executed by the processor 2al. The medium may be various non-transitory storage media readable by the computer 2a, or may be a communication line connected to the communication interface 2a3. The processor 2al may be a CPU (Central Processing Unit). The memory 2a2 may include a RAM (Random Access Memory), a ROM (Read Only Memory), an HDD (Hard Disk Drive), an SSD (Solid State Drive), or a combination thereof. The communication interface 2a3 may communicate with the plasma processing apparatus 1 via a communication line such as a LAN (Local Area Network) or the like.

In the above-described embodiment, the case in which the plasma formed in the plasma processing apparatus 1 is capacitively-coupled plasma (CCP) has been described. However, the plasma formed in the plasma processing space may be inductively coupled plasma (ICP), electron-cyclotron-resonance plasma (ECR plasma), helicon wave excited plasma (HWP), or surface wave plasma (SWP). In addition, various types of plasma generators may be used, including an alternating current (AC) plasma generator and a direct current (DC) plasma generator. In one embodiment, the AC signal (AC power) used in the AC plasma generator has a frequency in a range of 100 kHz to 10 GHz. Thus, the AC signal includes an RF (Radio Frequency) signal and a microwave signal. In one embodiment, the RF signal has a frequency in a range of 100 kHz to 150 MHz.

Although various exemplary embodiments have been described above, the present disclosure is not limited to the above-described exemplary embodiments. Various additions, omissions, substitutions, and modifications may be made. In addition, constituent elements in different embodiments may be combined with each other to form other embodiments.

### <Additive Manufacturing Method>

Next, the additive manufacturing method for a semiconductor manufacturing equipment component (the base 1110, the ring assembly 112, and/or the shower head 13 in the example shown in FIG. 1) made of a silicon-containing material and provided in the plasma processing system configured as described above will be described.

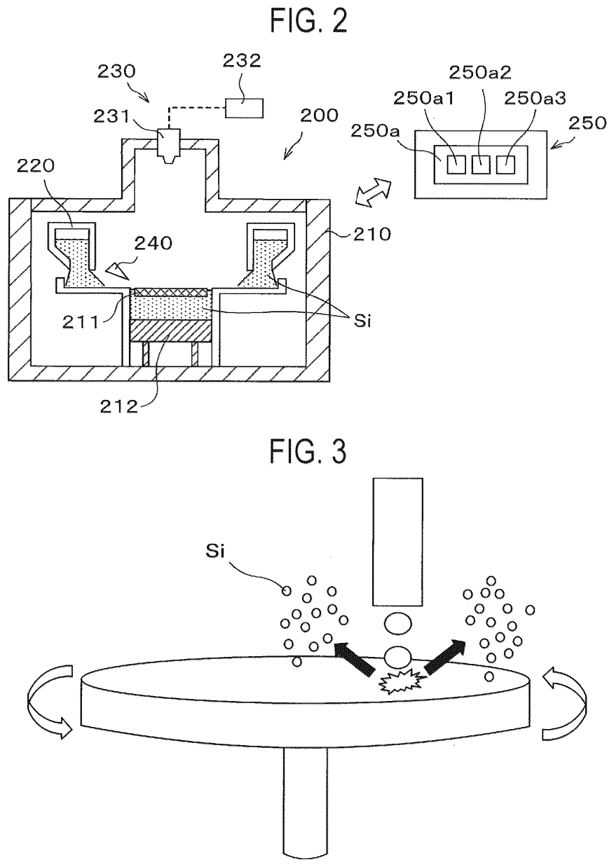

The additive manufacturing process according to the embodiment is performed inside an additive manufacturing apparatus 200. FIG. 2 is an explanatory diagram showing an outline of a configuration of the additive manufacturing apparatus 200 according to the embodiment.

As shown in FIG. 2, the additive manufacturing apparatus 200 includes a chamber 210, a powder storage 220, an electron beam (EB) irradiation system (hereinafter referred to as EB irradiation system) 230, and a recoater 240.

A manufacturing plate 211 is arranged as a base plate inside the chamber 210 as a vacuum processing container. An additive manufacturing for the semiconductor manufacturing equipment component is performed on a surface of the manufacturing plate 211. The manufacturing plate 211 may be made of the same material as a solidification material described below (in the present embodiment, silicon (Si: 4.3 ppm (room temperature)) or a material with a similar coefficient of thermal expansion (for example, a material with a coefficient of thermal expansion equal to or lower than that of titanium (Ti: 8.8 ppm (room temperature))). The manufacturing plate 211 may be configured so that its temperature is controlled by a temperature adjuster (not shown). As an example, the temperature adjuster may be a heater, a heat transfer medium, a flow path, an EB irradiation system 230 described below, or a combination thereof. A temperature sensor (not shown) for measuring the temperature of the manufacturing plate 211 may be connected to the manufacturing plate 211.

A lifting table 212 capable of adjusting a height of the manufacturing plate 211 is provided below the manufacturing plate 211. Silicon powder from a powder storage 220 described later may be supplied toward an upper surface of the manufacturing plate 211. The manufacturing plate 211 may be moved with a lifting operation of the lifting table 212 between a silicon powder supply position and a manufacturing position where a manufacturing electron beam is irradiated.

The powder storage 220 stores a material (solidification material) which is a raw material for the semiconductor manufacturing equipment component molded by the additive manufacturing method according to the embodiment and is melted and solidified by the irradiation of the manufacturing electron beam (hereinafter sometimes simply referred to as an “electron beam”) from the EB irradiation system 230 described later, for example, pure silicon powder (Si) with a purity of 99% or more in the present embodiment. The purity of 99% or more is, for example, a purity of 99.99%, 99.999%, and 99.9999%. When even higher purity is required, the purity may be, for example, 99.999999999%.

In one embodiment, the silicon powder as the solidification material has an average powder particle size (D50) of preferably 25 μm or more and 300 μm or less, more preferably 80 μm or more and 150 μm or less. The average powder particle size (D50) of the silicon powder may be measured by, for example, an existing particle size analysis-laser diffraction and scattering method (JIS Z8825). The particle size at which a cumulation in a particle size distribution converted in terms of a volume is 50% may be employed.

In one embodiment, the silicon powder as the solidification material may be produced by disk atomization, which is a powder production method in the related art. Specifically, in the manufacture of the silicon powder by the disk atomization, as shown in FIG. 3, molten silicon is dropped onto a disk rotating at a high speed. The molten silicon is scattered as fine droplets by a rotational force of the disk, thereby producing the silicon powder. By producing the silicon powder by the disk atomization, it is possible to manufacture powder having a shape closer to a perfect sphere than other powder production methods such as gas atomization. In addition, since a gas is not used in powder production unlike the gas atomization, gas entrainment in the powder production is suppressed, and defects such as an inflow of gas components into the produced silicon powder and the like are few. Further, according to this production method, the silicon powder is generated only by dropping the molten silicon onto the rotating disk, which makes it possible to produce the silicon powder at a relatively low cost.

The silicon powder stored in the powder storage 220 is supplied onto the manufacturing plate 211 arranged at the silicon powder supply position inside the chamber 210.

The solidification material stored in the powder storage 220 is not limited to the above-mentioned pure silicon (Si), and may be a composite material powder obtained by integrating pure silicon (Si) with another type of powder. In this case, examples of the material (compositing material) to be integrated with the pure silicon (Si) may include a nonmetallic material such as carbon (C), silicon carbide (SiC), alumina (Al₂O₃), aluminum nitride (AlN), yttrium oxide (Y₂O₃) or the like, and a metallic material such as aluminum (Al) or the like.

Further, in one embodiment, the composite material powder as the solidification material preferably has an overall average powder particle size (D50) of 25 μm or more and 300 μm or less, and a particle size equal to or larger than the average powder particle size of the powder to be composited with the pure silicon (see FIG. 4). In this case, the powder to be composited with the pure silicon (silicon carbide (SiC) in the illustrated example) does not need to be completely covered with the pure silicon, but is preferably bonded to an extent that it does not separate during flow. The average powder particle size (D50) of the composite material powder or the powder composited with the pure silicon may be measured by, for example, the existing particle size analysis-laser diffraction and scattering method (JIS Z8825), and the particle size at which the cumulation in the particle size distribution converted in terms of the volume is 50% may be used.

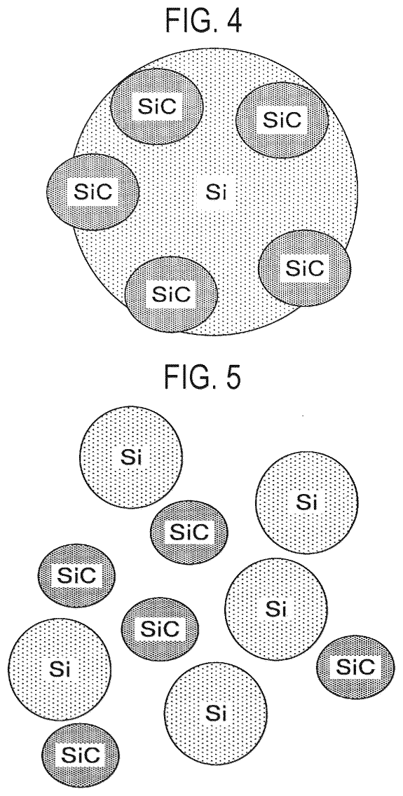

Further, a plurality of powder storages 220 may be arranged in the additive manufacturing apparatus 200. In each of the plurality of powder storages 220, powder of another type of solidification material for mixing with the pure silicon powder (Si) and the composite material powder may be stored in addition to the above-mentioned pure silicon powder (Si) and composite material powder. In this case, as the mixing material for mixing with the pure silicon powder (Si) and the composite material powder, for example, at least one mixing material selected from non-metallic materials such as carbon (C), silicon carbide (SiC), alumina (Al₂O₃), aluminum nitride (AlN), yttrium oxide (Y₂O₃) or ceramics, metallic materials such as aluminum (Al), or composite materials such as MMC (Metal Matrix Composites) may be stored. In the embodiment, the “mixing” of powder refers to a state in which different types of powders are simply mixed together as independent powders (a state in which they may be sieved) as shown in FIG. 5, unlike the state in which a plural type of powder are combined (integrated) as shown in FIG. 4.

In this case, in the additive manufacturing process described below, in addition to or instead of the additive manufacturing using the pure silicon powder (Si) alone as described above, additive manufacturing using mixed powder of the pure silicon powder (Si) and the nonmetallic material, the metallic material, or the compositing material may also be performed.

The EB irradiation system 230 includes an electron gun 231 as an irradiator disposed above the manufacturing plate 211 inside the chamber 210, and a head 232 as an irradiation source of the manufacturing electron beam irradiated from the electron gun 231. The manufacturing electron beam irradiated from the electron gun 231 is configured to be able to be irradiated to any position on the manufacturing plate 211 via, for example, a focusing mirror (not shown) or a polarizing mirror (not shown). In addition, a beam diameter of the manufacturing electron beam irradiated from the electron gun 231 is arbitrarily changeable.

The energy beam irradiated to the silicon powder on the manufacturing plate 211 is not limited to the electron beam, and may be, for example, a laser beam (SL: Selective Laser). In other words, the additive manufacturing apparatus 200 may be provided with a laser beam irradiation system (not shown) instead of the EB irradiation system 230.

The recoater 240 is disposed inside the chamber 210 at a position at least above the manufacturing plate 211. The recoater 240 is configured to be movable horizontally, and performs an operation of spreading the silicon powder from the powder storage 220 over the upper surface of the manufacturing plate 211 (so-called recoating).

An exhaust system (not shown) may be connected to the chamber 210. The exhaust system may include a pressure regulation valve and a vacuum pump. The pressure regulation valve regulates an internal pressure of the chamber 210. The vacuum pump may include a turbo molecular pump, a dry pump, or a combination thereof.

A powder recovery system (not shown) may be connected to the chamber 210. In one example, the powder recovery system may be connected to the exhaust system. The powder recovery system recovers the solidification material that was supplied onto the manufacturing plate 211 and was not used in the additive manufacturing process described below, that is, the solidification material that was not irradiated with the manufacturing electron beam from the EB irradiation system 230, and supplies the recovered solidification material again onto the manufacturing plate 211. This makes it possible to reuse the recovered solidification material.

In addition, as described above, when the plurality of powder storages 220 are arranged and the mixed powder in which the plurality of solidification materials are mixed is used, by selecting a combination in which the particle size distributions of the powder before mixing do not overlap with each other, it is possible to separate and recover the powder of the solidification materials before mixing from the mixed powder using the powder recovery system having a multi-stage sieve. In this way, by recovering the solidification material through the multi-stage sieve, it is possible to simultaneously recover different types of powder, and more appropriately reuse the solidification material.

Further, the additive manufacturing apparatus 200 configured as described above includes a controller 250. The controller 250 processes computer-executable instructions that cause the additive manufacturing apparatus 200 to execute various processes relating to the additive manufacturing process described in the present disclosure. The controller 250 may be configured to control individual elements of the additive manufacturing apparatus 200 to execute various processes described herein. In one embodiment, a part or the entirety of the controller 250 may be included in the additive manufacturing apparatus 200. The controller 250 may include a processor 250al, a memory 250a2, and a communication interface 250a3. The controller 250 is implemented by, for example, a computer 250a. The processor 250al may be configured to read a program from the memory 250a2 and execute the read program to perform various control operations. This program may be stored in the memory 250a2 in advance, or may be acquired via a medium when necessary. The acquired program is stored in the memory 250a2, and is read from the memory 250a2 and executed by the processor 250al. The medium may be various non-transitory storage media readable by the computer 250a, or may be a communication line connected to the communication interface 250a3. The processor 250al may be a CPU (Central Processing Unit). The memory 250a2 may include a RAM (Random Access Memory), a ROM (Read Only Memory), an HDD (Hard Disk Drive), an SSD (Solid State Drive), or a combination thereof. The communication interface 250a3 may communicate with the plasma processing apparatus 1 via a communication line such as a LAN (Local Area Network) or the like.

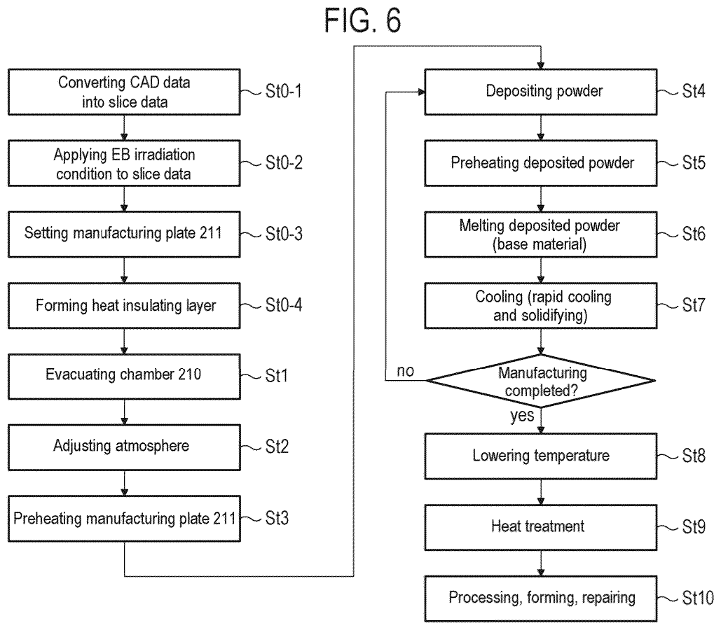

FIG. 6 is a flowchart showing an example of main operations of the additive manufacturing process performed using the additive manufacturing apparatus 200 configured as described above. In the following description, as described above, the pure silicon powder having a purity of 99% or more is used as the solidification material, and the semiconductor manufacturing equipment component is molded by an additive manufacturing process using an electron beam.

In the additive manufacturing of the semiconductor manufacturing equipment component, first, preliminary operations for the additive manufacturing are performed. Specifically, preliminary control operations relating to the additive manufacturing (Operations St0-1 to St0-2 in FIG. 6) and preliminary apparatus operations relating to the additive manufacturing (Steps St0-3 to St0-4 in FIG. 6) are sequentially performed.

In the preliminary control operations relating to the additive manufacturing, first, the CAD data (3D data) of the semiconductor manufacturing equipment component to be molded is converted into slice data (Step St0-1). Specifically, in the additive manufacturing process described later, a supply (stacking) of the solidification material to the manufacturing plate 211 and a cooling (solidification) of the supplied solidification material are repeated to manufacture the semiconductor manufacturing equipment component. Thus, the completed data (3D CAD data) of the semiconductor manufacturing equipment component to be molded is divided into unit data (slice data) per layer in a stacking direction of the solidification material.

Further, the additive manufacturing apparatus 200 applies supply conditions (supply position and supply amount (supply thickness)) of the solidification material and irradiation conditions of the manufacturing electron beam for each slice data (Step St0-2), and controls the irradiation of the manufacturing electron beam from the EB irradiation system 230 based on the determined irradiation conditions.

The CAD data of the semiconductor manufacturing equipment component used in the additive manufacturing process may be stored in the memory 250a2 in advance, or may be acquired via a storage medium when necessary.

In the preliminary apparatus operations relating to the additive manufacturing, first, the manufacturing plate 211 serving as a manufacturing substrate is placed at a predetermined position inside the chamber 210 (Step St0-3). At this time, a ground wire for avoiding charge accumulation and a temperature sensor for temperature control are connected to a lower portion of the manufacturing plate 211. After the manufacturing plate 211 is placed inside the chamber 210, a heat insulating layer is formed around the manufacturing plate 211 (Step St0-4). Specifically, as shown in FIG. 2, the lower portion of the manufacturing plate 211 placed inside the chamber 210 is filled with the pure silicon powder as the solidification material. By forming the heat insulating layer around the manufacturing plate 211 in this way, the temperature of the manufacturing plate 211 is prevented from decreasing during the additive manufacturing process described below, so that the additive manufacturing of the semiconductor manufacturing equipment component may be more effectively performed.

After the preliminary operations for the additive manufacturing are completed, the interior of the chamber 210 is evacuated by the exhaust system (not shown) (Step St1 in FIG. 6). In Step St1, it is desirable to evacuate the interior of the chamber 210 to a high degree of vacuum, preferably to 1.0×10⁻⁴ Torr or less.

When an internal pressure of the chamber 210 exceeds 1.0×10−4 Torr, or when the interior of the chamber 210 is simply replaced with an inert gas, an amount of impurities (for example, air, and the like) mixed into the semiconductor manufacturing equipment component molded by the additive manufacturing process according to the embodiment increases.

In this regard, according to the present embodiment, the amount of impurities in the interior of the chamber 210 may be reduced by evacuating the interior of the chamber 210 to 1.0×10−4 Torr or less. As a result, it is possible to manufacture the semiconductor manufacturing equipment component with low impurities.

After the evacuation of the interior of the chamber 210 ends, the inert gas (for example, helium (He) gas) is supplied from the gas supplier (not shown) into the chamber 210 to adjust an internal atmosphere of the chamber 210 (Step St2 in FIG. 6).

Subsequently, the manufacturing plate 211 is heated (preheated) before the silicon powder is supplied (Step St3 in FIG. 6). In Step St3, the temperature of the manufacturing plate 211 is increased to a temperature of 800 degrees C. or higher which is lower than a melting point of the solidification material (the silicon powder) that will be supplied in a subsequent operation.

In a series of subsequent additive manufacturing processes, the temperature of the manufacturing plate 211 is maintained at a preheating temperature (a temperature equal to or higher than 800 degrees C. and lower than the melting point of the silicon powder) until the manufacturing of the semiconductor manufacturing equipment component ends.

When the temperature of the manufacturing plate 211 falls below 800 degrees C., the silicon powder may scatter in a subsequent electron beam irradiation operation (Step St6 described below), which may require the stop of the additive manufacturing process.

On the other hand, when the preheating temperature of the manufacturing plate 211 is equal to or higher than the melting point of the silicon powder, the silicon powder may melt near the upper surface of the manufacturing plate 211, which may result in a positional deviation of the manufacturing plate 211. In addition, when the silicon powder melts and becomes viscous in this way, the silicon powder may adhere to the recoater 240 during the above-mentioned recoating process. As a result, the manufacturing plate 211 and the recoater 240 may adhere to each other.

The method of heating the manufacturing plate 211 is not particularly limited. For example, the manufacturing plate 211 may be heated using a heating mechanism (not shown) arranged inside or outside the manufacturing plate 211. Alternatively, the manufacturing plate 211 may be heated by irradiating a manufacturing electron beam from the EB irradiation system 230 arranged above the manufacturing plate 211 and heating the manufacturing plate 211 with the energy of the irradiated manufacturing electron beam.

After the manufacturing plate 211 is preheated to a desired temperature, the silicon powder stored in the powder storage 220 is supplied to and deposited on the manufacturing plate 211 (Step St4 in FIG. 6). At this time, the manufacturing plate 211 is placed at a silicon powder supply position by the lifting table 212. In Step St4, in order to appropriately melt the silicon powder layer (hereinafter sometimes referred to as “deposited powder”) deposited on the manufacturing plate 211 in the subsequent electron beam irradiation operation (Step St6 described later), it is desirable to control a deposition amount (supply amount) of the silicon powder so that a thickness (layer thickness) of the silicon powder deposited on the manufacturing plate 211 is close to the powder grain size of the silicon powder. The thickness of the silicon powder deposited on the manufacturing plate 211 is preferably 80 μm or more. However, the thickness of the silicon powder is not limited to 80 μm or more.

In one embodiment, the silicon powder supplied onto the manufacturing plate 211 is selected to have an average powder particle size (D50) of 25 μm or more and 300 μm or less, more preferably 80 μm or more and 150 μm or less.

When the average particle size of the silicon powder is less than 25 μm, the silicon powder may scatter in the subsequent electron beam irradiation operation (Step St6 described later), making it necessary to stop the additive manufacturing process, or a density of the semiconductor manufacturing equipment component to be molded may be reduced.

On the other hand, when the average particle size of the silicon powder exceeds 300 μm, even if the semiconductor manufacturing equipment component is manufactured, a manufacturing accuracy (resolution) of the semiconductor manufacturing equipment component may be reduced. This makes it difficult to manufacture the semiconductor manufacturing equipment component in a desired shape.

In contrast, when the average particle size of the silicon powder is 80 μm or more and 150 μm or less, the semiconductor manufacturing equipment component may be manufactured in the desired shape and density, while suitably suppressing the scattering of the silicon powder in the subsequent electron beam irradiation operation (Step St6 described later).

Further, in the electron beam irradiation operation (Step St6 described later), the scattering of the silicon powder is suppressed by irradiating one layer of silicon powder deposited on the manufacturing plate 211 with the manufacturing electron beam in multiple stages (plural times) as described later. However, by using the silicon powder having the average particle size of 80 μm or more in this way, it is possible to suppress the scattering of the silicon powder. Thus, as will be described later, the semiconductor manufacturing equipment component may be manufactured by irradiating the manufacturing electron beam in the single shot (one time) instead of irradiating the manufacturing electron beam in the multiple stages.

After the silicon powder is deposited on the manufacturing plate 211 at a desired thickness, the silicon powder as the deposited powder is heated (preheated) (Step St5 in FIG. 6). The silicon powder is heated to a desired preheat temperature (800 degrees C. or higher) by the transfer of heat from the preheated manufacturing plate 211, the above-mentioned heating mechanism (not shown) for heating the manufacturing plate 211, or the irradiation of the manufacturing electron beam from the EB irradiation system 230.

When the temperature of the silicon powder falls below 800 degrees C. as described above, the deposited silicon powder may scatter in the subsequent electron beam irradiation operation (Step St6 described below), which may require the manufacturing to be stopped.

Specifically, particularly when the silicon powder is irradiated with the electron beam in the subsequent electron beam irradiation operation (Step St6 described below), electric charges are accumulated in the silicon powder irradiated with the electron beam. In such a case, the Coulomb force is generated between the silicon powder particles in which the electric charges has been accumulated. As a result, the silicon powder may scatter.

Therefore, in the present embodiment, the deposited powder is preheated prior to the subsequent electron beam irradiation operation (Step St6 described below).

By heating the silicon powder in this manner, adjacent silicon powder particles are bonded to each other. As a result, a mechanical fastening force is generated between the silicon powder particles, and a weight per powder particle is increased. This prevents the silicon powder from scattering.

Further, according to the present embodiment, since the silicon powder particles are bonded to each other as described above, conductivity is improved. Thus, the charges accumulated by the irradiation of the electron beam may escape downward (toward the manufacturing plate 211) via the bonded silicon powder and the above-mentioned ground wire. This makes it possible to further appropriately prevent the silicon powder from scattering.

In Step St5, when the silicon powder is preheated by the irradiation of the manufacturing electron beam from the EB irradiation system 230, the temperature of the silicon powder is increased stepwise, particularly in an initial stage of the preheating. In other words, an output of the manufacturing electron beam is increased stepwise.

By increasing the output of the manufacturing electron beam stepwise in this manner, the accumulation of the electric charges is suppressed, particularly in the initial stage of the preheating when the bonding between the silicon powder particles has not progressed. This makes it possible to appropriately promote the bonding between the silicon powder particles and to suppress the scattering of the silicon powder.

When the silicon powder is preheated to a desired temperature, the EB irradiation system 230 irradiates the silicon powder on the manufacturing plate 211 with an electron beam (Step St6 in FIG. 6). At this time, the manufacturing plate 211 is placed at the manufacturing position by the lifting table 212. In Step St6, the irradiation position of the electron beam from the electron gun 231 is scanned on the manufacturing plate 211. In Step St6, the silicon powder on the manufacturing plate 211 is irradiated with the electron beam, thereby partially melting the silicon powder at the electron beam irradiation position. As a result, the silicon powder particles are bonded to each other. Hereinafter, a layer of the silicon powder formed on the manufacturing plate 211 by the bonding between the silicon powder particles may be referred to as a “molten silicon layer (molten layer).”

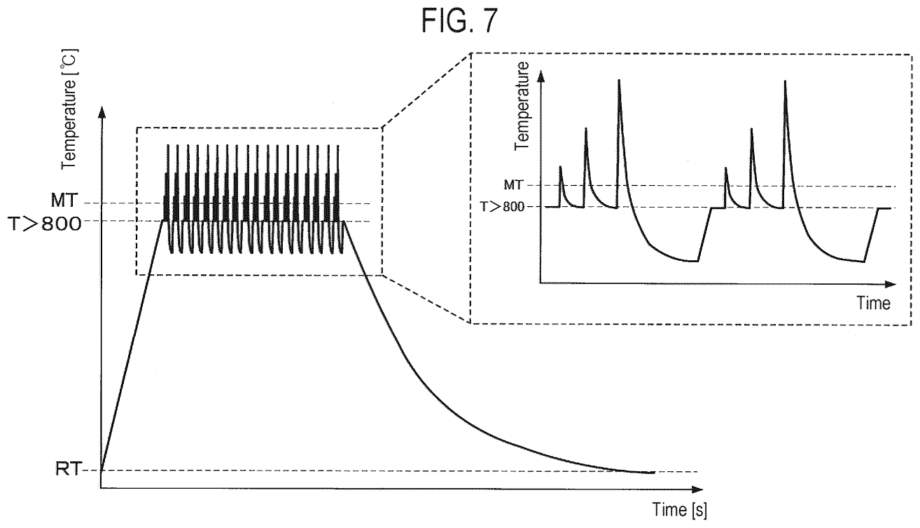

In Step St6, the silicon powder on the manufacturing plate 211 is irradiated with the electron beam in multiple stages (three stages in the example of FIG. 7) as shown in FIG. 7. A time interval between respective stages of the multiple-stage electron beam irradiation is controlled so that the silicon powder heated by the irradiation of a previous electron beam is cooled down to the preheating temperature (800 degrees C. or higher) before the irradiation of the electron beam, and then a next electron beam is irradiated.

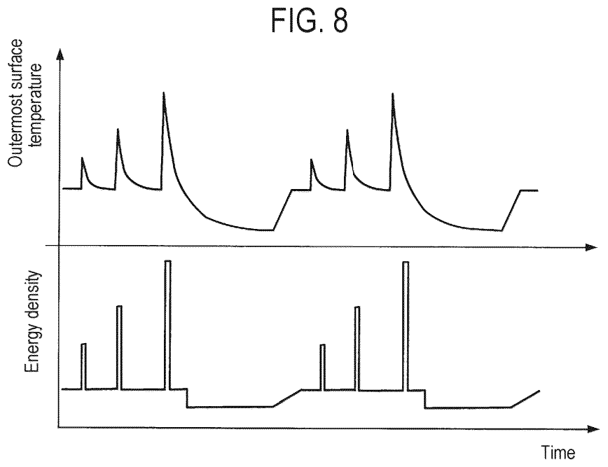

At this time, as shown in FIG. 8, the energy density of the electron beam irradiated in multiple stages is controlled so that a temperature of the outermost surface of the manufactured object (silicon powder which is a target of electron beam irradiation) increases stepwise. In other words, the irradiation of the electron beam is controlled so that an energy density of the electron beam irradiated in the latter stage among the electron beams irradiated in multiple stages is higher than that of the electron beam irradiated in the former stage.

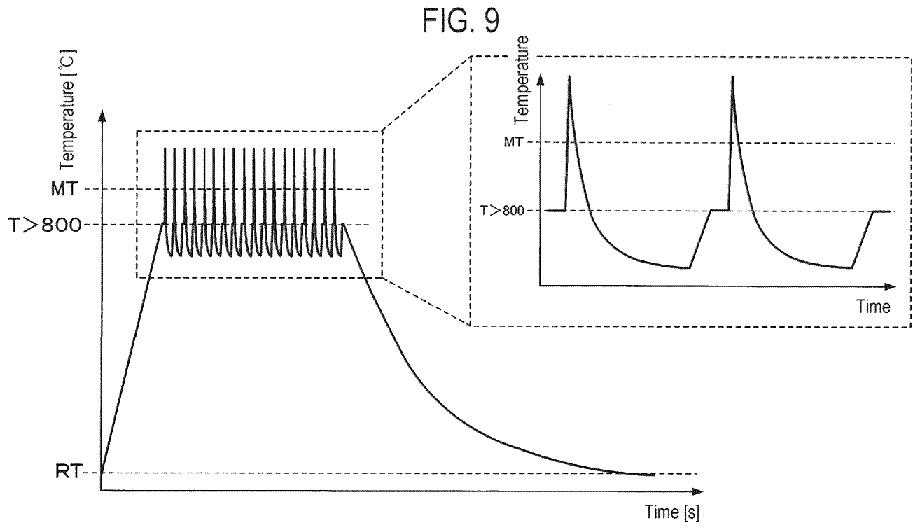

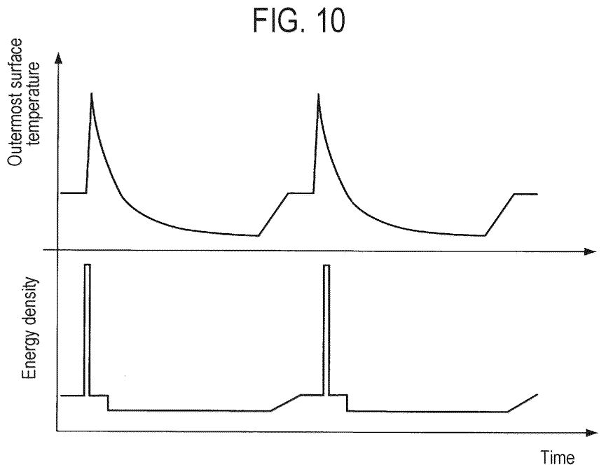

As described above, when the temperature of the silicon powder to be irradiated with the electron beam is less than 800 degrees C., the silicon powder may scatter when the electron beam is irradiated. However, on the other hand, even when the silicon powder is heated by the single-shot electron beam irradiation as shown in FIGS. 9 and 10, that is, even when the temperature of one silicon powder is increased at once by the single-shot electron beam irradiation, the silicon powder may scatter.

In this regard, in the additive manufacturing process according to the present embodiment, as shown in FIG. 7, the electron beam is irradiated in multiple stages (plural times) to one silicon powder so that the temperature of the silicon powder is increased in a stepwise manner. As a result, the silicon powder to be irradiated with the electron beam is melted and bonded to each other in a stepwise manner. Then, the silicon powder thus melted and bonded is irradiated with an electron beam (the last electron beam among the electron beams irradiated in multiple stages) for actually forming the molten silicon layer (the molten layer). In other words, in Step St6, the electron beams (the electron beams other than those of the last stage among the electron beams irradiated in multiple stages) for melting and bonding the silicon powder to each other in a stepwise manner and the electron beams (of the last stage among the electron beams irradiated in multiple stages) for actually forming the molten silicon layer from the silicon powder are irradiated in a successive manner.

As a result, in the electron beam irradiation operation (Step St6) of the additive manufacturing process according to the present embodiment, the molten silicon layer may be appropriately formed while suppressing the scattering of the silicon powder.

Further, as described above, when the silicon powder supplied onto the manufacturing plate 211 has an average particle size of 80 μm or more and the solidification material is composed of the pure silicon powder alone, the scattering of the solidification material due to the irradiation of the electron beam is suppressed by the increase in the weight per powder particle.

In view of this, when the solidification material is composed of the pure silicon powder alone and the average particle size of the silicon powder is 80 μm or more, the molten silicon layer may be formed by the single-shot (one time) electron beam irradiation as shown in FIG. 9 instead of the multiple-stage electron beam irradiation. In this way, the time required for manufacturing the semiconductor manufacturing equipment component may be significantly shortened by forming the molten silicon layer with the single-shot electron beam irradiation rather than the multiple-stage electron beam irradiation.

In order to appropriately form the molten silicon layer (the semiconductor manufacturing equipment component) by scanning the electron beam on the solidification material (the pure silicon powder) according to the embodiment, various parameters relating to the irradiation of the electron beam may be adjusted based on the following relational expression (1) or (2).

Relational expression(1)=([Voltage]×[Current])/([Beam diameter]×[Scan speed])

Relational expression(2)=([Voltage]×[Current])/([Beam diameter]×[Scan speed]×[Thickness of one powder layer])

The units of various parameters are as follows:
Voltage: [kV]
Current: [mA]
Beam diameter (diameter): [mm]
Scan speed: [mm/see]
Thickness of one powder layer (deposited powder): [mm]

In one embodiment, it is desirable that the relational expression (1) is 0.3 or more and 3.0 or less, more preferably 0.5 or more and 3.0 or less. In one embodiment, it is desirable that the relational expression (2) is 5.3 or more and 50.0 or less, more preferably 8.4 or more and 50.0 or less.

When the relational expression (1) exceeds 3.0 or when the relational expression (2) exceeds 50.0, the energy of the electron beam irradiated from the electron gun 231 becomes excessive, which may cause the silicon powder to melt excessively. This makes it difficult to appropriately control the shape of the molded semiconductor manufacturing equipment component.

On the other hand, when the relational expression (1) is less than 0.3, or when the relational expression (2) is less than 5.3, the energy of the electron beam irradiated from the electron gun 231 does not reach the required amount. Thus, the manufactured object (semiconductor manufacturing equipment component) may be peeled off from the manufacturing plate 211 during the additive manufacturing process performed by the additive manufacturing apparatus 200. This may make it difficult to continue the additive manufacturing process.

Further, when the relational expression (1) is 0.5 or more, or when the relational expression (2) is 8.4 or more, the manufactured object (semiconductor manufacturing equipment component) may be formed in a desired shape, and the density of the molded semiconductor manufacturing equipment component may be increased.

In view of the foregoing, in the present embodiment, it is desirable that the above-mentioned relational expression (1) is 0.3 or more and 3.0 or less, more preferably 0.5 or more and 3.0 or less, or the above-mentioned relational expression (2) is 5.3 or more and 50.0 or less, more preferably 8.4 or more and 50.0 or less.

Further, the above-mentioned relational expression (1) or the above-mentioned relational expression (2) may be applied to the irradiation conditions when the solidification material (the pure silicon powder) is irradiated with the single-shot electron beam, or to the irradiation conditions associated with at least the last-stage electron beam in the case of the multiple-stage electron beam irradiation.

After the silicon powder on the manufacturing plate 211 is melted to form the molten silicon layer, the molten silicon powder is cooled (Step St7 in FIG. 6). In Step St7, the molten silicon layer is solidified by the cooling. Hereinafter, the solidified molten silicon layer may be referred to as a “solidified silicon layer (solidified layer).”

It is desirable that the molten silicon layer be cooled in a short period of time, that is, that the molten silicon layer be rapidly cooled and solidified. Specifically, it is desirable that the cooling (solidification) time of the molten silicon layer is 1 second or less.

The method of cooling the molten silicon layer is not particularly limited. For example, the molten silicon layer may be cooled by natural heat dissipation in the interior of the chamber 210.

In the present embodiment, as shown in FIG. 6, a series of process cycles including the depositing the silicon powder (Step St4), the melting the silicon powder (Steps St5 and St6), and the solidifying the molten silicon layer (Step St7) are repeatedly executed until the desired shape of the semiconductor manufacturing equipment component is obtained.

In Step St4 subsequent to the second cycle, the pure silicon powder is supplied as a solidification material onto the solidified silicon layer (underlying material layer), which is formed in a previous cycle prior to the second cycle, in addition to the manufacturing plate 211.

In other words, in the additive manufacturing performed after the second cycle, the semiconductor manufacturing equipment component is molded by stacking another solidified silicon layer on one solidified silicon layer.

Thereafter, after the desired number of cycles is repeated, it is determined whether a further cycle of the additive manufacturing process (Steps St4 to St7) is necessary. When it is determined that the further cycle of the additive manufacturing process is necessary (when the manufacturing of the semiconductor manufacturing equipment component has not been completed), the process returns to Step St4 and the process of Steps St4 to St7 is repeated as shown in FIG. 6. In addition, when it is determined that the further cycle of the additive manufacturing process is not necessary (when the semiconductor manufacturing equipment component has been obtained in the desired shape), the additive manufacturing process ends.

When the additive manufacturing process ends, an internal temperature of the chamber 210 including the molded semiconductor manufacturing equipment component and the manufacturing plate 211 is decreased, and the molded semiconductor manufacturing equipment component and the manufacturing plate 211 are further heat-treated as necessary (Steps St8 and St9 in FIG. 6).

Thereafter, the molded semiconductor manufacturing equipment component is removed from the chamber 210. The semiconductor manufacturing equipment component removed from the chamber 210 may be machined, formed, or repaired as necessary (Step St10 in FIG. 6).

In the above-described embodiment, the cycle of the additive manufacturing process (Steps St4 to St7) has been described to be repeatedly executed, but such a repetition may be omitted depending on an intended use of the semiconductor manufacturing equipment component to be molded. In other words, the additive manufacturing process may be executed only once.

### <Method of Forming (Repairing) the Molded Semiconductor Manufacturing Equipment Component>

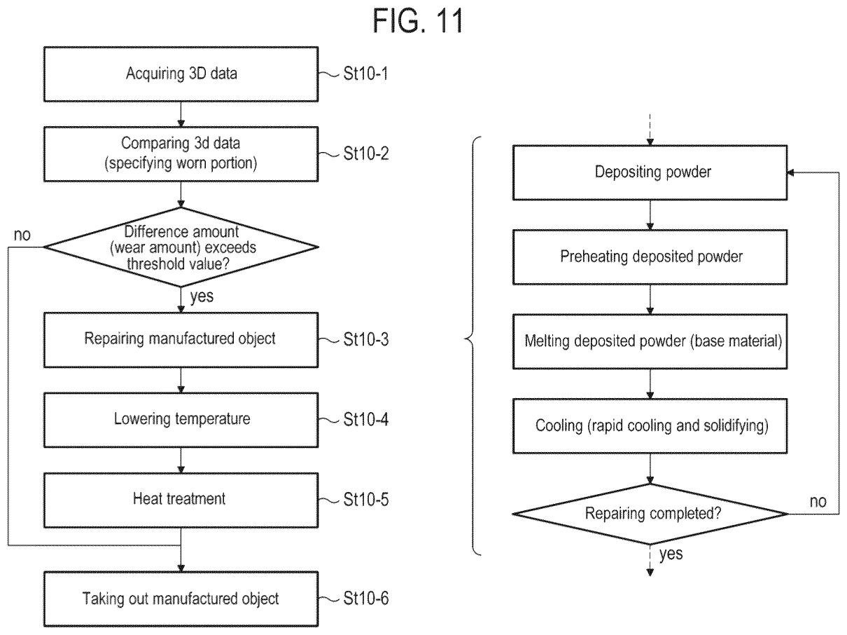

Next, an example of the method of forming (repairing: Step St10) the semiconductor manufacturing equipment component molded as described above will be described. FIG. 11 is a flowchart showing an example of main operations of a process of forming (repairing) the semiconductor manufacturing equipment component (hereinafter simply referred to as a “repairing process”). For example, the repairing process is performed on the silicon-containing semiconductor manufacturing equipment component worn by the plasma process performed in the interior of the plasma processing apparatus 1 of FIG. 1. In the example shown in FIG. 1, the silicon-containing semiconductor manufacturing equipment component worn by the plasma process is at least one of the base 1110, the ring assembly 112, or the shower head 13. In addition, the repairing process is performed not only on the semiconductor manufacturing equipment component worn by the plasma process, but also on the semiconductor manufacturing equipment component broken and/or damaged due to various factors.

When repairing the semiconductor manufacturing equipment component, first, 3D data of the semiconductor manufacturing equipment component to be repaired is acquired using a 3D scanner (Step St10-1 in FIG. 11). The 3D data is composed of data such as an amount of wear, a wear position (wear region), a wear shape and the like. The acquired 3D data is outputted to a control device (not shown) of the 3D scanner.

Subsequently, the 3D data acquired in Step St10-1 is compared with 3D data for forming the semiconductor manufacturing equipment component to be repaired (for example, CAD data used in Step St0-1 in FIG. 6) (Step St10-2 in FIG. 11). More specifically, the CAD data, which is the completed 3D data of the semiconductor manufacturing equipment component, is compared with the 3D data of the semiconductor manufacturing equipment component to be repaired acquired in Step St10-1 to acquire a difference value between these two pieces of data. When the acquired difference value (the amount of wear) exceeds a predetermined threshold value, a portion where this difference value exceeds the threshold value is specified as a portion that needs to be repaired in the semiconductor manufacturing equipment component to be repaired (hereinafter referred to as “worn portion”).

After the worn portion of the semiconductor manufacturing equipment component is specified, the repair of the semiconductor manufacturing equipment component (Step St10-3 in FIG. 11) begins. In one example, the method of repairing the semiconductor manufacturing equipment component is the same as the additive manufacturing process shown in FIG. 6, and is performed using, for example, the additive manufacturing apparatus 200 described above.

That is, the worn portion specified in Step St10-2 is regarded as a processing target portion in the additive manufacturing process. A cycle of a series of repairing processes including supplying the silicon powder to the worn portion, depositing the silicon powder, heating (preheating) the silicon powder, irradiating the silicon powder with the electron beam, and cooling the molten silicon powder is repeatedly performed.

However, in the repairing process on the semiconductor manufacturing equipment component, the silicon powder is supplied onto the semiconductor manufacturing equipment component to be repaired instead of onto the above-mentioned manufacturing plate 211. In view of this viewpoint, in the series of repairing processes, the temperature of the semiconductor manufacturing equipment component instead of the manufacturing plate 211 is maintained preferably at least at the preheating temperature (the temperature of 800 degrees C. or higher and lower than the melting point of the silicon powder) until the repairing process on the semiconductor manufacturing equipment component ends. Further, it is preferable that at least the semiconductor manufacturing equipment component is made of the same material as the solidification material or a material having a coefficient of thermal expansion close to that of the manufacturing plate 211. In other words, a material that is the same as the material constituting the semiconductor manufacturing equipment component or a material having a coefficient of thermal expansion close to that of the manufacturing plate 211 may be selected as the solidification material.

In the repairing process on the semiconductor manufacturing equipment component, when the above-mentioned pure silicon powder is used as the solidification material, it is desirable to adjust the irradiation conditions of the electron beam based on the above-mentioned relational expression (1) or the above-mentioned relational expression (2). In addition, other conditions relating to the repairing process, such as conditions of the silicon powder deposited on the semiconductor manufacturing equipment component to be repaired (type, particle size, mixing ratio, and the like), the internal pressure of the chamber 210, the method of heating the semiconductor manufacturing equipment component, and the like, may be the same as those in the above-mentioned additive manufacturing method.

Subsequently, after the cycle is repeated a desired number of times, it is determined whether or not a further cycle of the repairing process is necessary. When it is determined that the further cycle of the repairing process is necessary (when the repairing process on the semiconductor manufacturing equipment component is not completed), the repairing process is repeated again. When it is determined that the further cycle of the repairing process is not necessary (when the semiconductor manufacturing equipment component has been repaired to have the desired shape), the repairing process ends.

After the repairing process ends, the interior of the chamber 210 including the repaired semiconductor manufacturing equipment component and the manufacturing plate 211 is cooled (Step St10-4 in FIG. 11), and the repaired semiconductor manufacturing equipment component and the manufacturing plate 211 are further heat-treated as necessary (Step St10-5 in FIG. 11).

Thereafter, the repaired semiconductor manufacturing equipment component is taken out from the chamber 210 (Step St10-6 in FIG. 11), and the series of repairing processes on the semiconductor manufacturing equipment component ends.

When the difference value (the amount of wear) obtained in the above-mentioned 3D data comparison (Step St10-2) does not exceed the predetermined threshold value, as shown in FIG. 11, the semiconductor manufacturing equipment component may be unloaded from the interior of the chamber 210 (Step St10-6) without performing the repairing process on the semiconductor manufacturing equipment component (Steps St10-3 to St10-5).

### <Effects of the Additive Manufacturing Method According to the Embodiment>

With the additive manufacturing method according to the above-described embodiment, by setting the above-mentioned relational expression (1) to 0.3 or more and 3.0 or less, preferably 0.5 or more and 3.0 or less, or by setting the above-mentioned relational expression (2) to 5.3 or more and 50.0 or less, preferably 8.4 or more and 50.0 or less, it is possible to appropriately mold and repair the semiconductor manufacturing equipment component even when the pure silicon powder having a purity of 99% or more is used as the solidification material.

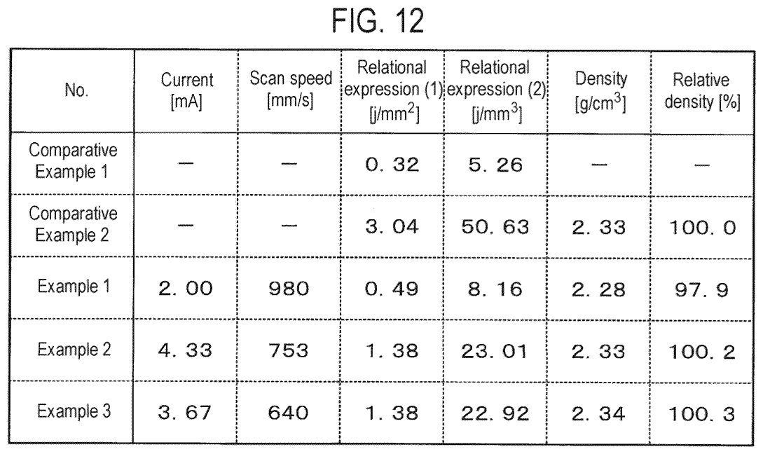

FIG. 12 is a table showing a density and relative density of the semiconductor manufacturing equipment component molded under each condition when the values of the above-mentioned relational expressions (1) and (2) are adjusted by changing various parameters.

The “density [g/cm³]” shown in FIG. 12 represents a measured density of the molded semiconductor manufacturing equipment component, and the “relative density [%]” represents a relative density of the semiconductor manufacturing equipment component when the density of the silicon powder as the solidification material is set to “100”.

In FIG. 12, Comparative Example 1 shows results when the relational expression (1) is 0.3 or more but the relational expression (2) is less than 5.3, Comparative Example 2 shows results when the relational expression (1) exceeds 3.0 and the relational expression (2) also exceeds 50.0.

In FIG. 12, Example 1 shows results when the relational expression (1) is 0.3 or more and less than 0.5 and the relational expression (2) is 5.3 or more and less than 8.4, and Examples 2 and 3 show results when the relational expression (1) is 0.5 or more and 3.0 or less and the relational expression (2) is 8.4 or more and 50.0 or less.

During the additive manufacturing under all conditions shown in FIG. 12, the temperature of the manufacturing plate 211 was constantly maintained at 800 degrees C. or higher.

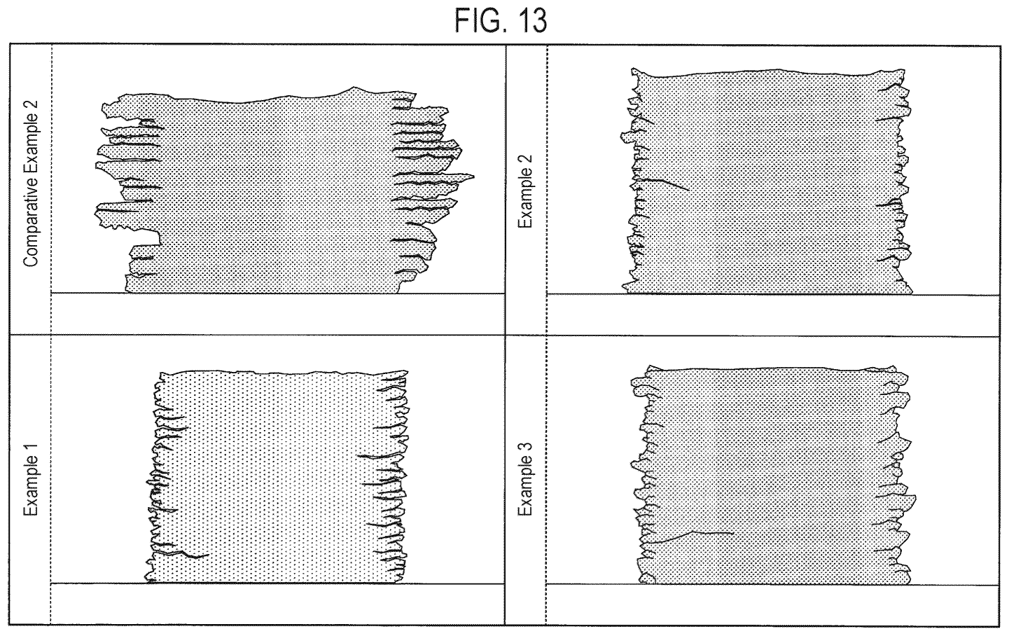

FIG. 13 is an explanatory diagram showing outlines of the semiconductor manufacturing equipment components molded under the respective conditions shown in FIG. 12. Specifically, the outlines of the semiconductor manufacturing equipment components molded under the conditions of the above-mentioned Comparative Example 2, Example 1, Example 2, and Example 3 are shown. These outlines are images captured by X-ray CT scanning.

In Comparative Example 1 of FIG. 12, the relational expression (2) was less than 5.3. As described above, the energy of the electron beam irradiated from the electron gun 231 was weak, and the manufactured object was peeled off from the manufacturing plate 211 during the additive manufacturing process. In other words, the semiconductor manufacturing equipment component could not be appropriately molded.

In Comparative Example 2 of FIG. 12, the relative density of the molded semiconductor manufacturing equipment component was 100.0. That is, impurities were not mixed from the state of the silicon powder as the solidification material, so that a dense semiconductor manufacturing equipment component having a relative density of over 99% was molded.

On the other hand, the relational expression (1) exceeded 3.0 and the relational expression (2) exceeded 50.0. As described above, the energy of the electron beam irradiated from the electron gun 231 was strong, and the shape of the molded semiconductor manufacturing equipment component was significantly distorted (became flattened) as shown in FIG. 13. In other words, a semiconductor manufacturing equipment component having a desired shape could not be obtained.

In Example 1 of FIG. 12, the shape of the semiconductor manufacturing equipment component was not distorted. That is, as shown in FIG. 13, a semiconductor manufacturing equipment component having a desired shape could be obtained.

On the other hand, under the condition that the relational expression (1) is 0.3 or more and less than 0.5, and the relational expression (2) is 5.3 or more and less than 8.4, the density of the molded semiconductor manufacturing equipment component was decreased (relative density of 97.9%).

In Example 2 and Example 3 of FIG. 12, the condition that the relational expression (1) is 0.5 or more and 3.0 or less, and the relational expression (2) is 8.4 or more and 50.0 or less was satisfied. As a result, the relative density of the semiconductor manufacturing equipment component molded as shown in FIG. 12 was 100.2 in Example 2 and 100.3 in Example 3. That is, impurities were not mixed from the state of the silicon powder as the solidification material, so that a dense semiconductor manufacturing equipment component having a relative density of over 99% was molded.

In addition, as shown in FIG. 13, the shape of the semiconductor manufacturing equipment component was not distorted. That is, a semiconductor manufacturing equipment component having a desired shape was obtained.

As described above, the present inventors have found that, as shown in FIGS. 12 and 13, when the pure silicon powder (having a purity of 99% or more) is used as the solidification material, a manufactured object (semiconductor manufacturing equipment component) may be formed in a desired shape by satisfying the condition that the above-described relational expression (1) is 0.3 or more and 3.0 or less, or the above-described relational expression (2) is 5.3 or more and 50.0 or less.

Further, the present inventors have found that a manufactured object (semiconductor manufacturing equipment component) having a high density (relative density of 99% or more) may be formed in a desired shape by satisfying the condition that the above-described relational expression (1) is 0.5 or more and 3.0 or less, or the above-described relational expression (2) is 8.4 or more and 50.0 or less.

Further, the present inventors have found that in the additive manufacturing process using an electron beam, a crystalline structure (crystalline structure of silicon) of a manufactured object (semiconductor manufacturing equipment component) may be controlled by adjusting an output current of the electron beam and a scan speed of the electron beam. In other words, the semiconductor manufacturing equipment component may be controlled to be monocrystalline silicon or polycrystalline silicon by adjusting the current and scan speed of the electron beam.

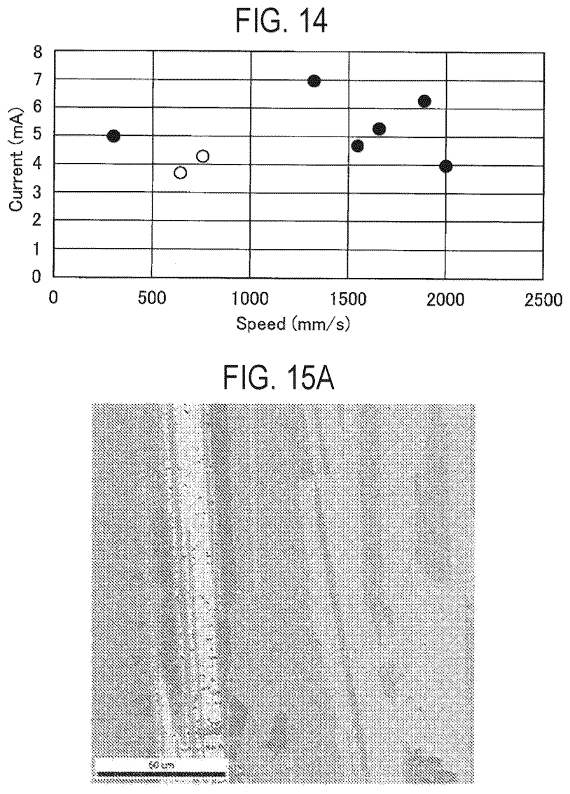

Specifically, the present inventors have conducted the additive manufacturing process under conditions in which the current and scan speed of an electron beam were varied as shown in FIG. 14, and observed the crystalline structure of the molded semiconductor manufacturing equipment component. As a result, under the conditions indicated by the white circles (◯) in FIG. 14, the crystalline structure became a monocrystalline structure, and under the conditions indicated by the black circles (●), the crystalline structure became a polycrystalline structure.

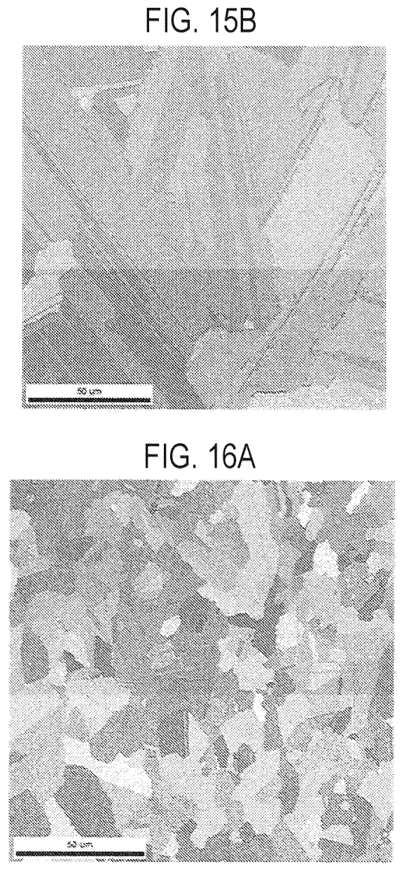

FIGS. 15A and 15B show polycrystalline structures in cross sections of the semiconductor manufacturing equipment component. FIG. 15A shows the cross section parallel to a manufacturing direction, and FIG. 15B shows the cross section perpendicular to the manufacturing direction. The shading of color in FIGS. 15A and 15B indicate a crystallite orientation, and crystals with the same shading of color are crystals having the same orientation. This polycrystalline structure was obtained under one condition indicated by the black circle (●) in FIG. 14, that is, a condition that the current is 4.00 mA and the scan speed is 2,000 mm/s. As shown in FIGS. 15A and 15B, a plurality of crystallite grains with different orientations are formed even in the cross section in each orientation. In addition, a semiconductor manufacturing equipment component having a polycrystalline structure was molded similarly even under another condition indicated by the black circle (●).

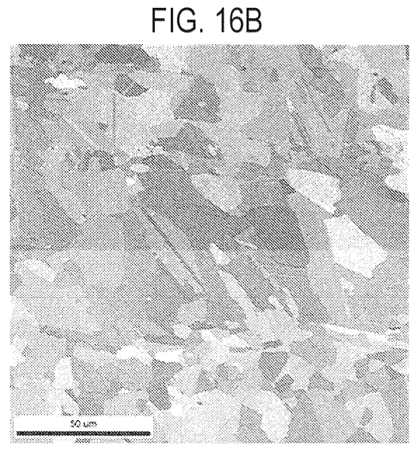

FIGS. 16A and 16B show monocrystalline structures in cross sections of the semiconductor manufacturing equipment component. FIG. 16A shows the cross section parallel to the manufacturing direction, and FIG. 16B shows the cross section perpendicular to the manufacturing direction. The shading of color in FIGS. 16A and 16B indicate the crystallite orientation as in FIGS. 15A and 15B, and the crystals with the same shading of color are crystals having the same orientation. This monocrystalline structure was obtained under one condition indicated by the white circle (O) in FIG. 14, that is, a condition that the current is 3.67 mA and the scan speed is 640 mm/s, which corresponds to Example 3 shown in FIG. 12. As shown in FIGS. 16A and 16B, a monocrystalline structure with approximately the same orientation was obtained in the cross section in either orientation. In addition, a semiconductor manufacturing equipment component having a monocrystalline structure was molded similarly even under another condition indicated by the white circle (O), that is, a condition that the current is 4.33 mA and the scan speed is 753 mm/s, which corresponds to Example 2 shown in FIG. 12.

Here, the smaller the current of the electron beam and the slower the scan speed, the easier it is for crystals to grow and for a monocrystalline structure to be formed. Based on the example shown in FIG. 14 above, a semiconductor manufacturing equipment component having a monocrystalline structure may be molded under the condition that the current of the electron beam is 4.33 mA or less and the scan speed is 753 mm/s or less.

Upper limits of the current and the scan speed for obtaining the monocrystalline structure are as described above. However, lower limits of the current and the scan speed are values that satisfy the condition that the above-mentioned relational expression (1) is 0.3 or more and 3.0 or less, or the above-mentioned relational expression (2) is 5.3 or more and 50.0 or less. In such a case, a semiconductor manufacturing equipment component having a desired shape may be obtained as described above.

As described above, by adjusting the scan speed of the electron beam, it is possible to control the crystalline structure of the molded semiconductor manufacturing equipment component. Further, in the case of the semiconductor manufacturing equipment component having a monocrystalline structure, it is possible to suppress a difference in the amount of wear in the plasma process for each grain boundary and crystallite grain, and to suppress a change in shape of a surface of the component, compared to the semiconductor manufacturing equipment component having a polycrystalline structure.

In the present embodiment, although the case in which the semiconductor manufacturing equipment component is molded by the additive manufacturing process has been described, a silicon substrate may be molded by the additive manufacturing process.

As described above, by satisfying the condition that the above-mentioned relational expression (1) is 0.3 or more and 3.0 or less, or the above-mentioned relational expression (2) is 5.3 or more and 50.0 or less, the silicon substrate may be molded in a desired shape. In particular, by satisfying the condition that the above-mentioned relational expression (1) is 0.5 or more and 3.0 or less, or the above-mentioned relational expression (2) is 8.4 or more and 50.0 or less, the silicon substrate may be molded in a desired shape and with high density (relative density of 99% or more).

In addition, by adjusting the scan speed of the electron beam as described above, it is possible to control the crystalline structure of the manufactured silicon substrate. Specifically, the silicon substrate having a monocrystalline structure may be molded under the condition that the current of the electron beam is 4.33 mA or less and the scan speed is 753 mm/s or less. In the case of the silicon substrate having a monocrystalline structure, a migration speed of electrons within the crystals is faster than that of the silicon substrate having a polycrystalline structure. For example, when the silicon substrate is used for an IC chip, the performance of the IC chip may be improved.

In the related art, when manufacturing a silicon substrate having a monocrystalline structure, there have been used a method of utilizing an unidirectional solidification such as a Bridgman method or the like, and a method of gradually growing a seed crystal while pulling up the seed crystal such as a Czochralski method or the like. Further, the silicon substrate having a monocrystalline structure are used in, for example, an IC chip, and is a material that is highly demanded in industries. However, when manufacturing the silicon substrate having a monocrystalline structure by using the method such as the Bridgman method or the Czochralski method, the manufacturing speed is slow. In particular, when using the Czochralski method, there is a limit to a manufacturable size.

In this regard, in the present embodiment, the silicon substrate is molded by the additive manufacturing process using an electron beam, so that the silicon substrate may be manufactured at a high speed and in a desired shape. Further, by adjusting the scan speed of the electron beam as described above, the crystalline structure of the silicon substrate may be controlled to a monocrystalline structure.

As described above, in the related art, the additive manufacturing method has been mainly applied to the manufacture of a component using a conductive metallic material, but the additive manufacturing method needs to be applied to the manufacture of a component using a semiconductor material such as high-purity silicon. In this regard, by applying the additive manufacturing method according to the present embodiment, it is possible to manufacture a component using silicon powder (semiconductor material).

According to the additive manufacturing method of the above-described embodiment, in the process cycles (Steps St4 to St7) that are repeatedly executed as shown in FIG. 6, each of the molten silicon layers formed in the respective cycles is cooled and solidified in each cycle (Step St7).

In this way, the silicon powder supplied onto the manufacturing plate 211 is cooled after the melting, which makes it possible to stabilize the temperature of the manufacturing plate 211 and to stabilize a manufacturing quality of the semiconductor manufacturing equipment component.

Further, according to the additive manufacturing method of the above-described embodiment, the temperature of the manufacturing plate 211 for forming the semiconductor manufacturing equipment component or the temperature of the semiconductor manufacturing equipment component to be repaired is maintained at 800 degrees C. or higher during the series of additive manufacturing processes shown in FIG. 6, more specifically, during Steps St3 to St7 shown in FIG. 6.

This suppresses the silicon powder supplied onto the manufacturing plate 211 or the semiconductor manufacturing equipment component from scattering during the series of additive manufacturing processes, and makes it possible to more appropriately mold the semiconductor manufacturing equipment component.

Further, according to the additive manufacturing apparatus 200 of the present embodiment, the manufacturing plate 211 serving as a base plate is made of the same material as the solidification material (in the present embodiment, silicon (Si: RT=4.3 ppm)) or a material having a similar coefficient of thermal expansion (for example, a material having a coefficient of thermal expansion equal to or lower than that of titanium (Ti: RT=8.8 ppm)). This suppresses occurrence of a large difference in the amount of thermal expansion between the manufacturing plate 211 and the solidification material when they are heated during the additive manufacturing process. As a result, the manufactured object is appropriately prevented from peeling off from the manufacturing plate 211 during the process.

In the above-described embodiment, the example has been described in which the electron beam is irradiated to the powder deposited on the manufacturing plate 211 in the additive manufacturing process, or on the semiconductor manufacturing equipment component in the repairing process, to form the molten layer. However, the manufacturing electron beam irradiated to the deposited powder may be a laser beam as described above.

In the above-described embodiment, at least one of the base 1110, the ring assembly 112, or the shower head 13 shown in FIG. 1 is shown as an example of the semiconductor manufacturing equipment component to be molded. However, the semiconductor manufacturing equipment component to be molded is not limited thereto.

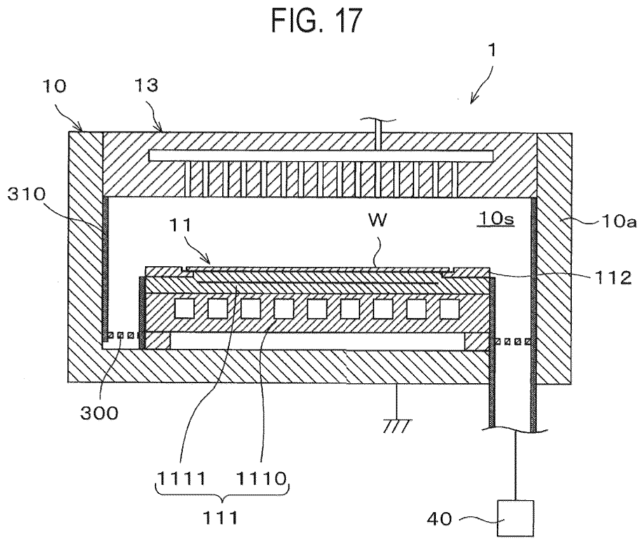

For example, the semiconductor manufacturing equipment component molded by the additive manufacturing process according to the technology of the present disclosure may be a baffle plate 300 (see FIG. 17) arranged to surround the periphery of the substrate support 11 in a plan view. In addition, for example, the semiconductor manufacturing equipment component molded by the additive manufacturing process according to the technique of the present disclosure may be a shield member 310 (see FIG. 17) arranged along the sidewall 10a or the side surface of the substrate support 11 in the interior of the processing chamber 10.

In the above-described embodiment, the case in which the solidification material is silicon powder having a purity of 99% or more has been described. However, the purity of the silicon powder used does not necessarily have to be 99% or more. In other words, the solidification material may be a silicon-containing material.

Specifically, the solidification material used for the powder utilized in the above-mentioned manufacturing may be composite material powder (see FIG. 4) in which pure silicon (Si) and another type of powder other than the pure silicon (Si) are integrated. In this case, examples of the material to be combined with the pure silicon (Si) may include a nonmetallic material such as carbon (C), silicon carbide (SiC), alumina (Al₂O₃), aluminum nitride (AlN), yttrium oxide (Y₂O₃) or the like, and a metallic material such as aluminum (Al) or the like.

In other words, the additive manufacturing apparatus 200 according to the present embodiment may manufacture a semiconductor manufacturing equipment component using pure silicon powder (Si) and/or a composite material powder containing at least one of the nonmetallic material or the metallic material in addition to the pure silicon powder (Si).

Hereinafter, a case in which a composite powder (composite material powder) composed of pure silicon powder (Si) and silicon carbide (SiC) as a nonmetallic material is used will be described by way of example. A semiconductor manufacturing equipment component that may be manufactured from the composite material powder composed of the pure silicon powder (Si) and the silicon carbide (SiC) as a nonmetallic material is, for example, a base 1110. By forming the base 1110 using the composite material powder composed of the pure silicon powder (Si) and the silicon carbide (SiC), it is possible to reduce a difference between the coefficient of thermal expansion of the base 1110 and the coefficient of thermal expansion of the electrostatic chuck 1111. This makes it possible to suppress the influence of thermal stress generated between the base 1110 and the electrostatic chuck 1111 during the plasma process.

The irradiation condition of the electron beam on the solidification material (for example, the above-mentioned relational expression (1) or the above-mentioned relational expression (2)) may be changed depending on a composite ratio and composition of silicon (Si) and silicon carbide (SiC) constituting the solidification material. In view of this, a case in which when performing the additive manufacturing using the composite material powder in this way, the composite ratio of silicon and silicon carbide constituting the solidification material is known, that is, the solidification material is constituted at a predetermined composite ratio, will be described by way of example. In addition, it is desirable that the silicon and silicon carbide constituting the solidification material are completely chemically separated from each other. Appropriate conditions for these powders may vary depending on the type of powder due to the influence of the composite ratio, composite form, particle size, and the like. Therefore, it is desirable to select appropriate conditions for each powder.

In addition, the particle size and shape of the silicon carbide to be composited with silicon are not particularly limited. From the viewpoint of suppressing scattering of the composite material powder during the additive manufacturing process as described above, it is desirable that the average particle size of the composite material powder as a whole is 80 μm or more and greater than or equal to the average particle size of the silicon carbide to be composited with silicon (see FIG. 4). In this case, it is not necessary for the silicon carbide to be completely covered with silicon. It is desirable that the silicon carbide is bonded to silicon to an extent that they are not separated from each other during flowing.

Further, when the manufacturing is performed using the composite material composed of silicon (Si) and silicon carbide (SiC) in this manner, regardless of the average particle size of the solidification material, the composite material may be irradiated with an electron beam by the multi-stage electron beam irradiations as shown in FIGS. 7 and 8, or may be irradiated with an electron beam by the single-shot (one time) electron beam irradiations as shown in FIGS. 9 and 10. The manufacturing electron beam irradiated to the deposited powder may be a laser beam as described above.

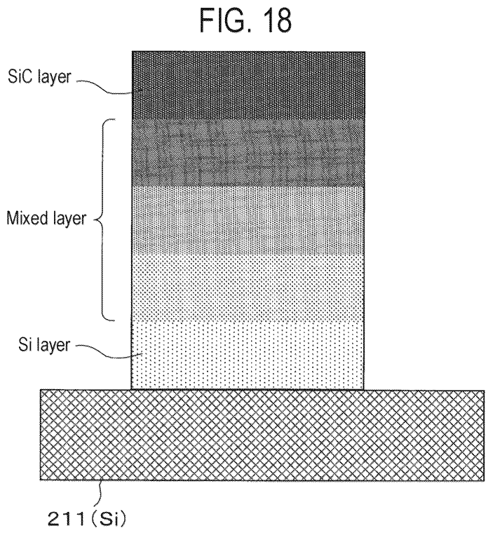

When the additive manufacturing process is performed using the composite material composed of silicon (Si) and silicon carbide (SiC), the semiconductor manufacturing equipment component to be molded may have a structure in which the mixing ratio of silicon (Si) and silicon carbide (SiC) is gradually changed (referred also to as a “gradation additive structure”) (see FIG. 18).

Specifically, for example, when the manufacturing process is performed on the manufacturing plate 211 made of silicon (Si) using the composite material composed of silicon (Si) and silicon carbide (SiC), first, the manufacturing process is performed using powder (preferably, the pure silicon powder) having a high ratio of silicon whose coefficient of thermal expansion is close to that of the manufacturing plate 211 (see a Si layer in FIG. 18).

Subsequently, as the cycle of the additive manufacturing process (Steps St4 to St7 shown in FIG. 6) is repeated, the powder is gradually replaced with powder having a high ratio of silicon carbide (SiC) (see a mixed layer in FIG. 18). As a replacement method used at that time, as described above, a plurality of powder storages 220 may be arranged in the additive manufacturing apparatus 200, different types of powder having different mixing ratios of silicon (Si) and silicon carbide (SiC) may be stored in the plurality of powder storages 220, and the powder storage 220 configured to supply the powder may be switched according to the progress of the process. A degree of the change in the ratio of the silicon carbide with the progress of the cycle of the process is not particularly limited. It is desirable to increase the ratio of the silicon carbide as gradually as possible. For example, as the cycle of the additive manufacturing process is repeated, the powder having a relatively high silicon carbide ratio is gradually replaced in a continuous manner or in a stepwise manner. When the powder is replaced with the powder having a relatively high silicon carbide ratio in a stepwise manner, it is preferable to set each stage more finely.

Thereafter, the cycle of the additive manufacturing process is progressed, and lastly, the manufacturing process is performed using the powder having a relatively high silicon carbide ratio (preferably, the pure silicon carbide powder) (see the SiC layer in FIG. 18).

Further, the used powder is in a state in which various composite materials are mixed to the power. As described above, by adjusting the particle size so that the particle size distributions of various types of powder do not overlap each other, it is possible to separate the powder from the mixed state using the multi-stage sieve.

Further, when the ratio of the silicon carbide is changed in this way, the electron beam irradiation conditions are appropriately changed to conditions suitable for that ratio as described above.

According to the additive manufacturing process of the present embodiment using the mixed powder, as described above, the semiconductor manufacturing equipment component is molded by gradually changing the mixing ratio of silicon (Si) and silicon carbide (SiC), in other words, by grading the mixing ratio. Thus, a bonding force may be generated between members (materials) having different coefficient of thermal expansions. That is, even when the materials having different coefficient of thermal expansions are used, a manufactured object (semiconductor manufacturing equipment component) may be appropriately molded.

Further, according to the present embodiment, as described above, in the initial stage of the additive manufacturing process, the manufacturing is performed using powder having a relatively high ratio of silicon, which has a coefficient of thermal expansion close to that of the manufacturing plate 211. This not only suppresses peeling between the different members (Si—SiC) as described above, but also properly suppresses peeling between the manufacturing plate 211 and the manufactured object (semiconductor manufacturing equipment component).

Further, according to the present embodiment, different materials may be bonded to each other without having to use an adhesive. When the different materials are bonded to each other with the adhesive, a thermal resistance between the different materials may increase, and thus a thermal conductivity may decrease. However, according to the present embodiment, different materials may be bonded to each other without having to use the adhesive. Therefore, it is possible to obtain a component by bonding different materials having a relatively high thermal conductivity to each other.

Further, by grading the mixing ratio of the silicon powder and the composite material in this way, it is possible to eliminate a need to restrict the coefficient of thermal expansions of the manufacturing plate 211 and the solidification material, that is, a need to approximately match the coefficient of thermal expansions of the manufacturing plate 211 and the solidification material, particularly in the latter half of the additive manufacturing process. As a result, as long as the coefficient of thermal expansions of the solidification material and the manufacturing plate 211 are approximately the same at least in the initial stage of the additive manufacturing process, the type of solidification material is not particularly limited. This greatly improved a degree of freedom of design of the semiconductor manufacturing equipment component to be molded.

In addition, by grading the mixing ratio of the silicon powder and the composite material in this manner, physical properties (thermal properties and/or electrical properties) of an interior of the molded semiconductor manufacturing equipment component may be adjusted arbitrarily. As a result, regions with different physical properties may be intentionally created in the interior of the semiconductor manufacturing equipment component. As a result, the semiconductor manufacturing equipment component may be appropriately designed according to the purpose of substrate processing in the plasma processing system shown in FIG. 1.

In addition, the additive manufacturing process in which the mixing ratio of the solidification material is changed in a gradual manner is not limited to the additive manufacturing using the mixed powder of silicon (Si) and a non-metallic material (silicon carbide (SiC) in the above example), but may also be applied to an additive manufacturing using a mixed powder of silicon (Si) and the above-mentioned metallic material (for example, aluminum (Al)).

For example, the shower head 13 shown in FIG. 1 may be integrally constructed by the additive manufacturing using silicon and aluminum. In this case, a plasma-processed surface of the shower head 13 (the lower surface of the shower head 13 in the example shown in FIG. 1) is manufactured with silicon, and the opposite surface thereof is manufactured with aluminum.

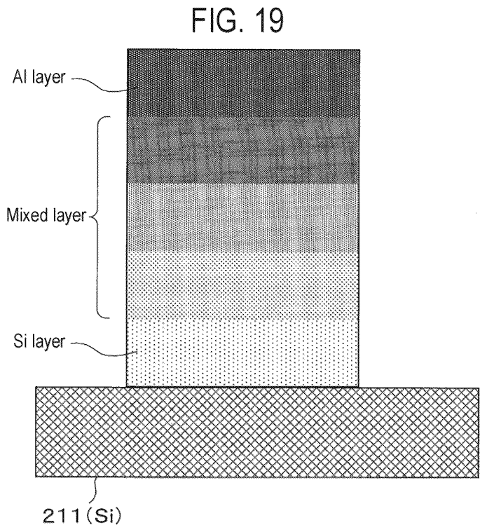

Specifically, first, the manufacturing is performed using powder having a relatively high ratio of silicon (preferably, the pure silicon powder) whose coefficient of thermal expansion is close to that of the manufacturing plate 211 (see a Si layer in FIG. 19).

Subsequently, as the cycle of the additive manufacturing process (Steps St4 to St7 shown in FIG. 6) is repeated, the powder is gradually replaced with powder having a relatively high ratio of aluminum (Al) to form a gradation additive structure composed of silicon and aluminum (see a mixed layer in FIG. 19). For example, as the cycle of the additive manufacturing process is repeated, the powder is gradually replaced with the powder having a relatively high ratio of aluminum in a continuous manner or in a stepwise manner. When replacing with the powder having a relative high ratio of aluminum in a stepwise manner, it is desirable to set each stage more finely.

Thereafter, the cycle of the additive manufacturing process is progressed, and lastly, the manufacturing is performed using the powder having a relatively high ratio of aluminum (preferably, the pure aluminum powder) (see an Al layer in FIG. 19).

The additive manufacturing process of gradually changing the mixing ratio of the solidification material may also be applied to an additive manufacturing using composite material powder composed of silicon (Si) and silicon carbide (SiC), and ceramic.

For example, the base 1110 made of the composite material powder composed of the above-described pure silicon powder (Si) and silicon carbide (SiC) and the electrostatic chuck 1111 made of ceramic may be integrated by the additive manufacturing.

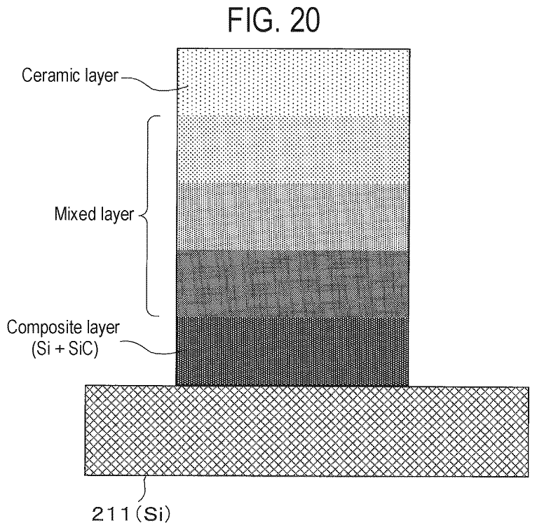

Specifically, first, as described above, the base 1110 is manufactured using the composite material powder composed of silicon (Si) and silicon carbide (SiC) (see a composite layer in FIG. 20).

Subsequently, as the cycle of the additive manufacturing process (Steps St4 to St7 shown in FIG. 6) is repeated, the powder is gradually replaced with powder having a relative high ratio of ceramic so that a gradation additive structure including the composite material powder composed of silicon (Si) and silicon carbide (SiC) and ceramic is manufactured (see a mixed layer in FIG. 20). For example, as the cycle of the additive manufacturing process is repeated, the powder is gradually replaced with the powder having a relatively high ratio of ceramic in a continuous manner or in a stepwise manner. When replacing with the powder having a relatively high ratio of ceramic in a stepwise manner, it is desirable to set each stage more finely.

Thereafter, the cycle of the additive manufacturing process is progressed, and lastly, the manufacturing is performed with the powder having a relatively high ratio of ceramic (preferably, the pure ceramic powder) (see a ceramic layer in FIG. 20).

According to the present disclosure in some embodiments, it is possible to appropriately manufacture, by an additive manufacturing method, a semiconductor manufacturing equipment component made of a material containing a high-purity silicon.

The embodiments disclosed herein should be considered as exemplary and not limitative in all respects. The above-described embodiments may be omitted, substituted, or modified in various forms without departing from the scope and spirit of the appended claims.

What is claimed is:

1. A method of additively manufacturing a high-purity silicon, the method comprising:
turning an interior of a vacuum processing container into a high vacuum state;
heating a base plate disposed in the interior of the vacuum processing container;
depositing silicon powder on the base plate;
forming a molten silicon layer by scanning an energy beam on the base plate; and
forming a solidified silicon layer by cooling the molten silicon layer,
wherein a cycle including the depositing the silicon powder, the forming the molten silicon layer, and the forming the solidified silicon layer is repeatedly executed.

2. The method of claim 1, further comprising:
heating the silicon powder prior to the forming the molten silicon layer.

3. The method of claim 2, wherein the energy beam is an electron beam.

4. The method of claim 3, wherein a manufacturing condition using the electron beam satisfies a condition where relational expression (1)=(voltage [kV]×current [mA])/(beam diameter [mm]×scan speed [mm/sec]) is 0.3 or more and 3.0 or less.

5. The method of claim 4, wherein the manufacturing condition satisfies a condition where relational expression (1) is 0.5 or more and 3.0 or less.

6. The method of claim 3, wherein a manufacturing condition using the electron beam satisfies a condition where relational expression (2)=(voltage [kV]×current [mA])/(beam diameter [mm]×scan speed [mm/sec]×thickness of one powder layer [mm]) is 5.3 or more and 50.0 or less.

7. The method of claim 6, wherein the manufacturing condition satisfies a condition where relational expression (2) is 8.4 or more and 50.0 or less.

8. The method of claim 2, wherein the energy beam is a laser beam.

9. The method of claim 1, wherein an internal pressure of the vacuum processing container in the high vacuum state is 1.0×10−4 Torr or less.

10. The method of claim 1, wherein in the heating the base plate, the base plate is heated by scanning the energy beam on the base plate.

11. The method of claim 10, wherein in the heating the base plate, the base plate is heated to 800 degrees C. or higher.

12. The method of claim 11, wherein a temperature of the base plate is maintained at 800 degrees C. or higher in a series of processes including at least the depositing the silicon powder, the forming the molten silicon layer, and the forming the solidified silicon layer.

13. The method of claim 12, wherein a coefficient of thermal expansion of the base plate is 8.8 ppm or less.

14. The method of claim 13, wherein the base plate is made of at least one of silicon or titanium.

15. The method of claim 1, wherein the silicon powder has a powder purity of 99% or more and a powder particle size of 25 μm or more and 300 μm or less.

16. The method of claim 15, wherein a powder particle size of the silicon powder is 80 μm or more and 150 μm or less, and
wherein in the forming the molten silicon layer, the silicon powder is irradiated with the energy beam in a single shot.

17. The method of claim 2, wherein the silicon powder is composited with at least one compositing material selected from a group of consisting of C, SiC, Al₂O₃, AlN, Y₂O₃ and Al.

18. The method of claim 17, wherein a powder particle size of the silicon powder is 80 μm or more and 150 μm or less and is equal to or larger than an average particle size of the compositing material to be composited with the silicon powder.

19. The method of claim 2, wherein the silicon powder deposited on the base plate is mixed with a mixing material,
wherein a mixing ratio of the mixing material to the silicon powder is arbitrarily changeable, and
wherein the mixing ratio of the mixing material is increased as the cycle is repeatedly executed.

20. The method of claim 19, wherein the mixing material is at least one selected from a group consisting of C, SiC, Al₂O₃, AlN, Y₂O₃, Al and ceramic.

21. The method of claim 1, wherein in the forming the molten silicon layer, the silicon powder is successively irradiated with the energy beam a plurality of times.

22. The method of claim 21, wherein an energy density of the energy beam irradiated later among the successively-irradiated energy beams is made higher than an energy density of the energy beam irradiated immediately before.

23. A method of additively manufacturing a semiconductor manufacturing equipment component, the method comprising:
turning an interior of a vacuum processing container into a high vacuum state;
heating a base plate disposed in the interior of the vacuum processing container;
depositing silicon powder on the base plate;
forming a molten silicon layer by scanning an energy beam on the base plate; and
forming a solidified silicon layer by cooling the molten silicon layer,
wherein a cycle including the depositing the silicon powder, the forming the molten silicon layer, and the forming the solidified silicon layer is repeatedly executed.

24. The method of claim 23, further comprising:
heating the silicon powder prior to the forming the molten silicon layer.

25. The method of claim 24, wherein the energy beam is an electron beam.

26. The method of claim 25, wherein a manufacturing condition using the electron beam satisfies a condition where relational expression (1)=(voltage [kV]×current [mA])/(beam diameter [mm]×scan speed [mm/sec]) is 0.3 or more and 3.0 or less.

27. The method of claim 26, wherein the manufacturing condition satisfies a condition where relational expression (1) is 0.5 or more and 3.0 or less.

28. The method of claim 25, wherein a manufacturing condition using the electron beam satisfies a condition where relational expression (2)=(voltage [kV]×current [mA])/(beam diameter [mm]×scan speed [mm/sec]×thickness of one powder layer [mm]) is 5.3 or more and 50.0 or less.

29. The method of claim 28, wherein the manufacturing condition satisfies a condition where relational expression (2) is 8.4 or more and 50.0 or less.

30. The method of claim 24, wherein the energy beam is a laser beam.

31. The method of claim 23, wherein an internal pressure of the vacuum processing container in the high vacuum state is 1.0×10−4 Torr or less.

32. The method of claim 23, wherein in the heating the base plate, the base plate is heated by scanning the energy beam on the base plate.

33. The method of claim 32, wherein in the heating the base plate, the base plate is heated to 800 degrees C. or higher.

34. The method of claim 33, wherein a temperature of the base plate is maintained at 800 degrees C. or higher in a series of processes including at least the depositing the silicon powder, the forming the molten silicon layer, and the forming the solidified silicon layer.

35. The method of claim 34, wherein a coefficient of thermal expansion of the base plate is 8.8 ppm or less.

36. The method of claim 35, wherein the base plate is made of at least one of silicon or titanium.

37. The method of claim 23, wherein the silicon powder has a powder purity of 99% or more and a powder particle size of 25 μm or more and 300 μm or less.

38. The method of claim 37, wherein a powder particle size of the silicon powder is 80 μm or more and 150 μm or less, and
wherein in the forming the molten silicon layer, the silicon powder is irradiated with the energy beam in a single shot.

39. The method of claim 24, wherein the silicon powder is composited with at least one compositing material selected from a group consisting of C, SiC, Al₂O₃, AlN, Y₂O₃ and Al.

40. The method of claim 39, wherein a powder particle size of the silicon powder is 80 μm or more and 150 μm or less and is equal to or larger than an average particle size of the compositing material to be composited with the silicon powder.

41. The method of claim 24, wherein the silicon powder deposited on the base plate is mixed with a mixing material,
wherein a mixing ratio of the mixing material to the silicon powder is arbitrarily changeable, and
wherein the mixing ratio of the mixing material is increased as the cycle is repeatedly executed.

42. The method of claim 41, wherein the mixing material is at least one selected from a group consisting of C, SiC, Al₂O₃, AlN, Y₂O₃, Al and ceramic.

43. The method of claim 23, wherein the semiconductor manufacturing equipment component to be additively manufactured is at least one selected from a group consisting of a base of a substrate support configured to support a substrate to be processed, a ring assembly arranged to surround a periphery of the substrate, and an upper electrode arranged above the substrate support.

44. The method of claim 43, wherein the substrate support includes the base, and an electrostatic chuck disposed above the base and having a holding surface for the substrate, and wherein the base and the electrostatic chuck are integrally additively manufactured.

45. A semiconductor manufacturing equipment component molded by an additive manufacturing process, comprising:
turning an interior of a vacuum processing container into a high vacuum state;
heating a base plate disposed in the interior of the vacuum processing container;
depositing silicon powder on the base plate;
forming a molten silicon layer by scanning an energy beam on the base plate; and
forming a solidified silicon layer by cooling the molten silicon layer,
wherein a cycle including the depositing the silicon powder, the forming the molten silicon layer, and the forming the solidified silicon layer is repeatedly executed.

46. The semiconductor manufacturing equipment component of claim 45, wherein the silicon powder has a powder purity of 99% or more and a powder particle size of 25 μm or more and 300 μm or less.

47. The semiconductor manufacturing equipment component of claim 45, wherein the silicon powder is composited with at least one compositing material selected from a group consisting of C, SiC, Al₂O₃, AlN, Y₂O₃ and Al.

48. The semiconductor manufacturing equipment component of claim 47, wherein a powder particle size of the silicon powder is 80 μm or more and 150 μm or less and is equal to or larger than an average particle size of the compositing material to be composited with the silicon powder.

49. The semiconductor manufacturing equipment component of claim 45, wherein the silicon powder deposited on the base plate is mixed with a mixing material,
wherein a mixing ratio of the mixing material to the silicon powder is arbitrarily changeable, and
wherein the mixing ratio of the mixing material is increased as the cycle is repeatedly executed.

50. The semiconductor manufacturing equipment component of claim 49, wherein the mixing material is at least one selected from a group consisting of C, SiC, Al₂O₃, AlN, Y₂O₃, Al and ceramic.

51. A method of forming a semiconductor manufacturing equipment component, the method comprising:
specifying a worn portion of the semiconductor manufacturing equipment component to be repaired;
turning an interior of a vacuum processing container into a high vacuum state;
heating the semiconductor manufacturing equipment component disposed in the interior of the vacuum processing container;
depositing silicon powder on the worn portion;
forming a molten silicon layer on the worn portion by scanning an energy beam on the worn portion; and
forming a solidified silicon layer on the worn portion by cooling the molten silicon layer,
wherein a cycle including the depositing the silicon powder, the forming the molten silicon layer, and the forming the solidified silicon layer is repeatedly executed.

52. The method of claim 51, further comprising:
heating the silicon powder prior to the forming the molten silicon layer.

53. The method of claim 52, wherein the energy beam is an electron beam.

54. The method of claim 53, wherein a manufacturing condition using the electron beam satisfies a condition where relational expression (1)=(voltage [kV]×current [mA])/(beam diameter [mm]×scan speed [mm/see]) is 0.3 or more and 3.0 or less.

55. The method of claim 54, wherein the manufacturing condition satisfies a condition where relational expression (1) is 0.5 or more and 3.0 or less.

56. The method of claim 53, wherein a manufacturing condition using the electron beam satisfies a condition where relational expression (2)=(voltage [kV]×current [mA])/(beam diameter [mm]×scan speed [mm/see]×thickness of one powder layer [mm]) is 5.3 or more and 50.0 or less.

57. The method of claim 56, wherein the manufacturing condition satisfies a condition where relational expression (2) is 8.4 or more and 50.0 or less.

58. The method of claim 52, wherein the energy beam is a laser beam.

59. The method of claim 51, wherein an internal pressure of the vacuum processing container in the high vacuum state is 1.0×10−4 Torr or less.

60. The method of claim 51, wherein in the heating the semiconductor manufacturing equipment component, the semiconductor manufacturing equipment component is heated by scanning the energy beam on the semiconductor manufacturing equipment component.

61. The method of claim 60, wherein in the heating the semiconductor manufacturing equipment component, the semiconductor manufacturing equipment component is heated to 800 degrees C. or higher.

62. The method of claim 61, wherein a temperature of the semiconductor manufacturing equipment component is maintained at 800 degrees C. or higher in a series of processes including at least the depositing the silicon powder, the forming the molten silicon layer, and the forming the solidified silicon layer.

63. The method of claim 62, wherein a coefficient of thermal expansion of the semiconductor manufacturing equipment component is 8.8 ppm or less.

64. The method of claim 63, wherein the semiconductor manufacturing equipment component is made of at least one of silicon or titanium.

65. The method of claim 51, wherein the silicon powder has a powder purity of 99% or more and a powder particle size of 25 μm or more and 300 μm or less.

66. The method of claim 65, wherein a powder particle size of the silicon powder is 80 μm or more and 150 μm or less, and
wherein in the forming the molten silicon layer, the silicon powder is irradiated with the energy beam in a single shot.

67. The method of claim 52, wherein the silicon powder is composited with at least one compositing material selected from a group consisting of C, SiC, Al₂O₃, AlN, Y₂O₃ and Al.

68. The method of claim 67, wherein a powder particle size of the silicon powder is 80 μm or more and 150 μm or less and is equal to or larger than an average particle size of the compositing material to be composited with the silicon powder.

69. The method of claim 52, wherein the silicon powder deposited on the semiconductor manufacturing equipment component is mixed with a mixing material,
wherein a mixing ratio of the mixing material to the silicon powder is arbitrarily changeable, and
wherein the mixing ratio of the mixing material is increased as the cycle is repeatedly executed.

70. The method of claim 69, wherein the mixing material is at least one selected from a group consisting of C, SiC, Al₂O₃, AlN, Y₂O₃, Al and ceramic.

71. The method of claim 51, wherein in the forming the molten silicon layer, the silicon powder is successively irradiated with the energy beam a plurality of times.

72. The method of claim 71, wherein an energy density of the energy beam irradiated later among the successively-irradiated energy beams is made higher than an energy density of the energy beam irradiated immediately before.
